(19) United States
(12) Patent Application Publication
(10) Pub. No.: US 2024/0081086 A1
(43) Pub. Date: Mar. 7, 2024

(54) LIGH-EMITTING ELEMENT AND LIGHT-EMITTING DEVICE

(71) Applicant: SHARP KABUSHIKI KAISHA, Sakai City, Osaka (JP)

(72) Inventors: Sentaro KIDA, Sakai City, Osaka (JP); YASUSHI ASAOKA, Sakai City, Osaka (JP)

(21) Appl. No.: 18/268,259

(22) PCT Filed: Dec. 22, 2020
(86) PCT No.: PCT/JP2020/047839

§ 371 Date: Jun. 19, 2023

(51) Int. Cl. H10K 50/115; C09K 11/02; C09K 11/56; C09K 11/88

(52) U.S. Cl. CPC H10K 50/115; C09K 11/02; C09K 11/565; C09K 11/881; C09K 11/883; H10K 2101/30

(57) ABSTRACT

A light-emitting element according to the present disclosure includes at least one pair of light-emitting layers formed between a cathode and an anode and the at least one pair of light-emitting layers includes, in a stated order from the cathode, a P-type light-emitting layer and an N-type light-emitting layer adjacent to each other.

### TECHNICAL FIELD

The present disclosure relates to a light-emitting element that includes quantum dots in its light-emitting layer, and to a light-emitting device that includes the light-emitting element.

### BACKGROUND ART

Various flat panel displays have been recently developed, among which display devices that include quantum-dot light-emitting diodes (QLEDs) or organic light-emitting diodes (OLEDs) as electric-field light-emitting elements have particularly gained the spotlight.

In such a QLED, a tandem structure, where a plurality of light-emitting layers including quantum dots (QDs) are stacked between the anode and the cathode, can improve external quantum efficiency (EQE).

Patent Literature 1 is directed to a tandem QLED.

### CITATION LIST

Patent Literature

Patent Literature 1: Japanese Unexamined Patent Application Publication No. 2008-177168 (published on Jul. 31, 2006)

### SUMMARY

### Technical Problem

However, such a knowntandem-structured QLED requires a carrier generation layer to be provided between its light-emitting layers. This increases the QLED's thickness, unfortunately raising the QLED's turn-on voltage.

In view of the above problem, the disclosure aims to improve the EQE of a light-emitting element that includes quantum dots in its light-emitting layer, and to reduce the thickness of the light-emitting element.

### Solution to Problem

To solve the above problem, a light-emitting element according to one aspect of the disclosure includes the following: a negative electrode; a positive electrode; and at least one pair of light-emitting layers formed between the negative electrode and the positive electrode, wherein the at least one pair of light-emitting layers includes a P-type quantum-dot light-emitting layer, and an N-type quantum-dot light-emitting layer including a second quantum dot (50, 152). The P-type quantum-dot light-emitting layer and the N-type quantum-dot light-emitting layer are adjacent to each other in the stated order from the cathode.

### Advantageous Effect of Disclosure

The foregoing configuration can improve the EQE of a light-emitting element that includes quantum dots in its light-emitting layer and can reduce the thickness of the light-emitting element.

### BRIEF DESCRIPTION OF DRAWINGS

FIG. 1 is a flowchart illustrating an example method for manufacturing a display device according to a first embodiment of the present disclosure.

FIG. 2 is a schematic sectional view of an example configuration of the display region of the display device according to the first embodiment of the present disclosure.

FIG. 3 is a schematic sectional view of an example stacked structure of a light-emitting element illustrated in FIG. 2.

FIG. 4 schematically illustrates an example configuration of a P-type quantum dot illustrated in FIG. 3.

FIG. 5 schematically illustrates an example configuration of an N-type quantum dot illustrated in FIG. 3.

FIG. 6 schematically illustrates example forbidden bands and Fermi levels of a first core illustrated in FIG. 4 and of a first shell illustrated in FIG. 4, and example forbidden bands and Fermi levels of a second core illustrated in FIG. 5 and of a second shell illustrated in FIG. 5.

FIG. 7 schematically illustrates other example forbidden bands and Fermi levels of the first core and first shell illustrated in FIG. 4, and other example forbidden bands and Fermi levels of the second core and second shell illustrated in FIG. 5.

FIG. 8 schematically illustrates example Fermi levels and forbidden bands of an anode, a hole injection layer, a hole transport layer, a second core, a first core, an electron transport layer and a cathode at the time when the light-emitting element illustrated in FIG. 3 does not emit light.

FIG. 9 schematically illustrates example Fermi levels and forbidden bands of the anode, hole injection layer, hole transport layer, second core, first core, electron transport layer and cathode at the time when the light-emitting element illustrated in FIG. 3 emits light.

FIG. 10 schematically illustrates example forbidden bands and Fermi levels of a first core and a first shell according to a second embodiment of the present disclosure, and example forbidden bands and Fermi levels of a second core and a second shell according to the second embodiment of the present disclosure.

FIG. 11 schematically illustrates the difference in carrier generation probability between the first embodiment and second embodiment of the present disclosure.

FIG. 12 schematically illustrates example Fermi levels and forbidden bands of an anode, a hole injection layer, a hole transport layer, a second core, a first core, an electron transport layer and a cathode at the time when a light-emitting element according to a third embodiment of the present disclosure does not emit light.

FIG. 13 schematically illustrates other example Fermi levels and forbidden bands of the anode, hole injection layer, hole transport layer, second core, first core, electron transport layer and cathode at the time when the light-emitting element according to the third embodiment of the present disclosure does not emit light.

FIG. 14 is a schematic sectional view of an example stacked structure of a light-emitting element according to a fourth embodiment of the present disclosure.

FIG. 15 is a schematic sectional view of another example stacked structure of the light-emitting element according to the fourth embodiment of the present disclosure.

FIG. 16 is a schematic sectional view of an example configuration of the display region of a display device according to a fifth embodiment of the present disclosure.

FIG. 17 is a schematic sectional view of an example configuration of the display region of a display device according to a sixth embodiment of the present disclosure.

FIG. 18 is a schematic sectional view of an example configuration of the display region of a display device according to a seventh embodiment of the present disclosure.

FIG. 19 schematically illustrates an example configuration of a lighting device according to an eighth embodiment of the present disclosure.

FIG. 20 schematically illustrates another example configuration of the lighting device according to the eighth embodiment of the present disclosure.

FIG. 21 schematically illustrates another example configuration of the lighting device according to the eighth embodiment of the present disclosure.

FIG. 22 schematically illustrates another example configuration of the lighting device according to the eighth embodiment of the present disclosure.

### DESCRIPTION OF EMBODIMENTS

### First Embodiment

In the Description, where the group of an element is designated with a Roman number, it is understood that the group is designated based on the nomenclature in the former CAS system. Further, where the group of an element is designated by an Arabic number, it is understood that the group is designated based on the element nomenclature in the current IUPAC system.

### Method for Manufacturing Display Device and Its Configuration

The term “in the same layer” hereinafter means that one layer is formed in the same process step (film formation step) as another layer, the term “under” hereinafter means that one layer is formed in a process step anterior to a process step of forming a comparative layer, and the term “over” hereinafter means that one layer is formed in a process step posterior to a process step of forming a comparative layer.

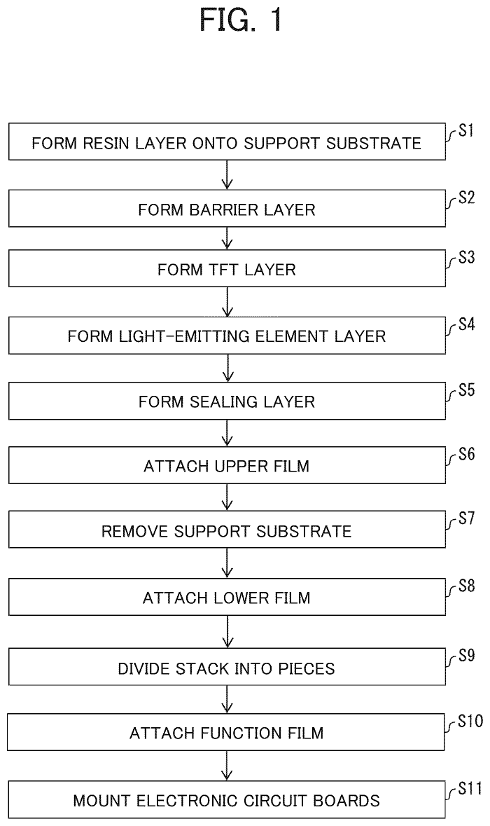

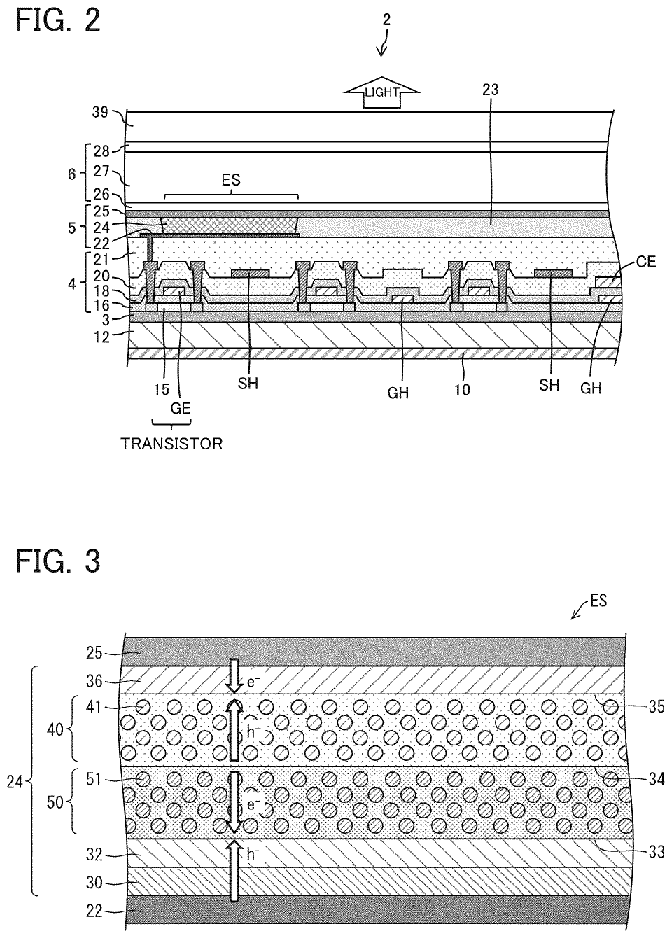

FIG. 1 is a flowchart illustrating an example method for manufacturing a display device. FIG. 2 is a schematic sectional view of an example configuration of the display region of a display device 2.

A flexible display device is manufactured through the following process steps illustrated in FIG. 1 and FIG. 2: the first process step (Step S1) is forming a resin layer 12 onto a light-transparent support substrate (e.g., mother glass). The next (Step S2) is forming a barrier layer 3. The next (Step S3) is forming a thin-film transistor layer 4 (TFT layer). The next (Step S4) is forming a top-emission light-emitting element layer 5. The next (Step S5) is forming a sealing layer 6. The next (Step S6) is attaching an upper film onto the sealing layer 6.

The next (Step S7) is removing the support substrate from the resin layer 12 through laser light irradiation or other methods. The next (Step S8) is attaching a lower film 10 onto the lower surface of the resin layer 12. The next (Step S9) is dividing a stack of the lower film 10, resin layer 12, barrier layer 3, thin-film transistor layer 4, light-emitting element layer 5 and sealing layer 6 into a plurality of pieces. The next (Step S10) is attaching a function film 39 onto the obtained pieces. The next (Step S11) is mounting electronic circuit boards (e.g., an IC chip and an FPC) onto a part (terminal section) of the outside (a non-display region or frame region) of the display region with a plurality of subpixels formed therein. It is noted that Steps S1 through S11 are performed by an apparatus (including a film formation apparatus that performs Steps S1 through S5) that manufactures a display device.

An example of the material of the resin layer 12 is polyimide. A portion of the resin layer 12 can be replaced with two resin films (e.g., polyimide films) and an inorganic sandwiched by them.

The barrier layer 3 protects the thin-film transistor layer 4 and light-emitting element layer 5 from intrusion of foreign substances, including water and oxygen, and can be composed of, for instance, a silicon oxide film, a silicon nitride film or a silicon oxide nitride film, all of which are formed through CVD, or this layer can be composed of, for instance, a laminate of these films.

The thin-film transistor layer 4 includes the following: a semiconductor film 15; an inorganic insulating film 16 (gate insulating film) over the semiconductor film 15; a gate electrode GE and a gate wire GH over the inorganic insulating film 16; an inorganic insulating film 18 (interlayer insulating film) over the gate electrode GE and gate wire GH; a capacitive electrode CE over the inorganic insulating film 18; an inorganic insulating film 20 (interlayer insulating film) over the capacitive electrode CE; a source wire SH over the inorganic insulating film 20; and a flattening film 21 (interlayer insulating film) over the source wire SH.

The semiconductor film 15 is composed of, for instance, low-temperature polysilicon (LTPS) or an oxide semiconductor (e.g., In—Ga—Zn—O semiconductor). Although FIG. 2 illustrates a transistor of top-gate structure, the transistor may be of bottom-gate structure.

The gate electrode GE, the gate wire GH, the capacitive electrode CE and the source wire SH are composed of, for instance, a metal monolayer film or a metal laminated film containing at least one of aluminum, tungsten, molybdenum, tantalum, chromium, titanium and copper.

The inorganic insulating films 16, 18 and 20 can be composed of, for instance, a silicon oxide (SiOx) film, a silicon nitride (SiNx) film or silicon oxide nitride (SiNO), all of which are formed through CVD, or a laminate of these films. The flattening film 21 can be composed of an organic material that can be applied, such as polyimide or acrylic.

The light-emitting element layer 5 includes the following: an anode 22 over the flattening film 21; an insulating edge cover 23 covering the edge of the anode 22; an active layer 24, which is an electroluminescence (EL) layer, over the edge cover 23; and a cathode 25 over the active layer 24. The edge cover 23 is formed by, for instance, applying an organic material, such as polyimide or acrylic, followed by patterning through photolithography. Either one of the anode 22 and cathode 25 is an island-shaped electrode (so called a pixel electrode) provided for each light-emitting element, and the other is a common electrode provided commonly throughout a plurality of light-emitting elements.

Each subpixel includes the anode 22 in the form of an island, the active layer 24, and the cathode 25, which form a light-emitting element ES (electric-field light-emitting element), which is a QLED, in the light-emitting-element layer 5; in addition, a subpixel circuit that controls the light-emitting element ES is formed in the thin-film transistor layer 4.

The active layer 24 is composed by, for instance, stacking a hole injection layer, a hole transport layer, a light-emitting layer, an electron transport layer and an electron injection layer sequentially from the bottom (the details will be described layer on). The light-emitting layer is formed in the form of an island together with the hole transport layer in the openings of the edge cover 23 (for each subpixel) through photolithography. The other layers are formed in the form of an island or in a flat manner (common layers). Further, a configuration where one or more of the hole injection layer, electron transport layer and electron injection layer is not formed is possible.

The anode 22 is a reflective electrode that is composed of, for instance, a stack of indium tin oxide (ITO) and silver (Ag) or a stack of ITO and Ag-containing alloy or is composed of, for instance, a Ag- or Al-containing material and has light reflectivity. The cathode (negative electrode) 25 is a transparent electrode that is composed of a light-transparency conductor, including a thin film of Ag, Au, Pt, Ni or Ir, a thin film of MgAg alloy, an ITO, and an indium zinc oxide (IZO). When the display device is a bottom-emission type rather than a top-emission type, the lower film 10 and the resin layer 12 are transparent to light, the anode 22 is a transparent electrode, and the cathode 25 is a reflective electrode.

In the light-emitting element ES, driving current between the anode 22 and cathode 25 causes a hole and an electron to recombine together within the light-emitting layer, thus generating an exciton, which emits light in the process of transition from the lowest unoccupied molecular orbital (LUMO) or conduction band level of a quantum dot to the highest occupied molecular orbital (HOMO) or valence band level of the same. When the light-emitting element ES is an OLED, a transition from the lowest unoccupied molecular orbital to the highest occupied molecular orbital can occur, and when the light-emitting element ES is a QLED, a transition from the conduction band level to the valence band level can occur. Although the Description describes a non-limiting example where the light-emitting element ES is a QLED, the light-emitting element ES may be an OLED.

The sealing layer 6 is transparent to light and includes an inorganic sealing film 26 covering the cathode 25, an organic buffer film 27 over the inorganic sealing film 26, and an inorganic sealing film 28 over the organic buffer film 27. The sealing layer 6, covering the light-emitting element layer 5, seals the light-emitting element layer 5 and prevents foreign substances, including water and oxygen, from permeating the light-emitting element layer 5.

The inorganic sealing film 26 and the inorganic sealing film 28 are each an inorganic insulating film and can be composed of, for instance, a silicon oxide film, a silicon nitride film or a silicon oxide nitride film, all of which are formed through CVD, or these films can be composed of, for instance, a laminate of these films. The organic buffer layer 27 is a light-transparency organic film having a flattening effect and can be made of an organic material that can be applied, such as acrylic. The organic buffer film 27 can be formed through ink-jet application for instance; a bank for stopping droplets may be provided in the non-display region.

The lower film 10 is, for instance, a PET film that is attached to the lower surface of the resin layer 12 after the removal of the support substrate, so that a highly flexible display device is achieved. The function film 39 has, for instance, at least one of the function of optical compensation, the function of touch sensing and the function of protection. Further, the function film 39 may include a color filter or a wavelength conversion layer. It is noted that a display device that includes at least one of a color filter and a wavelength conversion layer may include at least one of a color filter and a wavelength conversion layer separately from the function film 39 having the foregoing function.

The foregoing has described a flexible display device; manufacturing an inflexible display device, which typically requires no process steps, such as resin layer formation and base material replacement, includes, for instance, the stacking process step, i.e., Steps S2 through S5, onto a glass substrate, followed by Step S9. Further, manufacturing a non-flexible display device may include bonding a light-transparency sealing member with a sealing adhesive under a nitrogen atmosphere instead of, or in addition to the formation of the sealing layer 6. The light-transparency sealing member can be formed of a material, including glass and plastic, and preferably has a recessed shape.

One embodiment of the present disclosure is directed particularly to the active layer 24, included in the light-emitting element ES, among the components of the foregoing display device (light-emitting device) 2.

### Stacked Structure of Active Layer

FIG. 3 is a schematic sectional view of an example stacked structure of the light-emitting element ES illustrated in FIG. 2.

As illustrated in FIG. 3, the light-emitting element ES includes the anode (positive electrode) 22, the cathode (negative electrode) 25, and the active layer 24 formed between the anode 22 and the cathode 25.

The active layer 24 includes a pair of light-emitting layers 40 and 50, and the pair of light-emitting layers 40 50 includes a P-type light-emitting layer (P-type quantum-dot light-emitting layer) 40 and an N-type light-emitting layer (N-type quantum-dot light-emitting layer) 50 in the stated order from the cathode 25. The P-type light-emitting layer 40 includes P-type quantum dots 41 (first quantum dots), and the N-type light-emitting layer 50 includes N-type quantum dots 51 (second quantum dots). The P-type light-emitting layer 40 and the N-type light-emitting layer 50 are adjacent to each other. In the Description, a P-type light-emitting layer and a P-type quantum dot behave like a P-type semiconductor with regard to electrical conduction. Further, an N-type light-emitting layer and an N-type quantum dot behave like an N-type semiconductor with regard to electrical conduction. Further, the adjective “adjacent” implies that two layers are in direct contact without any intervention, or the two layers are in indirect contact with an intervention of a thin layer that allows electrons to tunnel.

Although the Description describes a configuration where the P-type light-emitting layer 40 behaves like a P-type semiconductor due to the P-type quantum dots 41, the scope of the disclosure is not limited to this configuration. The P-type light-emitting layer 40 may behave like a P-type semiconductor due to other reasons. Likewise, the N-type light-emitting layer 50 may behave like an N-type semiconductor due to reasons other than the N-type quantum dots 51. A conceivable example is forming a thin film containing an electron-attractive material between light-emitting layers in a pair, with such a thickness that electrons can tunnel through the thin film. In this case, one of the light-emitting layers in the pair adjacent to the cathode behaves like a P-type semiconductor, and the other light-emitting layer adjacent to the anode behaves like an N-type semiconductor.

The active layer 24 further includes a hole injection layer 30 and a hole transport layer 32 between the anode 22 and the N-type light-emitting layer 50 sequentially from the anode 22. The active layer 24 further includes an electron transport layer 36 between the cathode 25 and the P-type light-emitting layer 40. The active layer may further include an electron injection layer between the cathode 25 and the electron transport layer 36.

### Quantum Dot Configuration

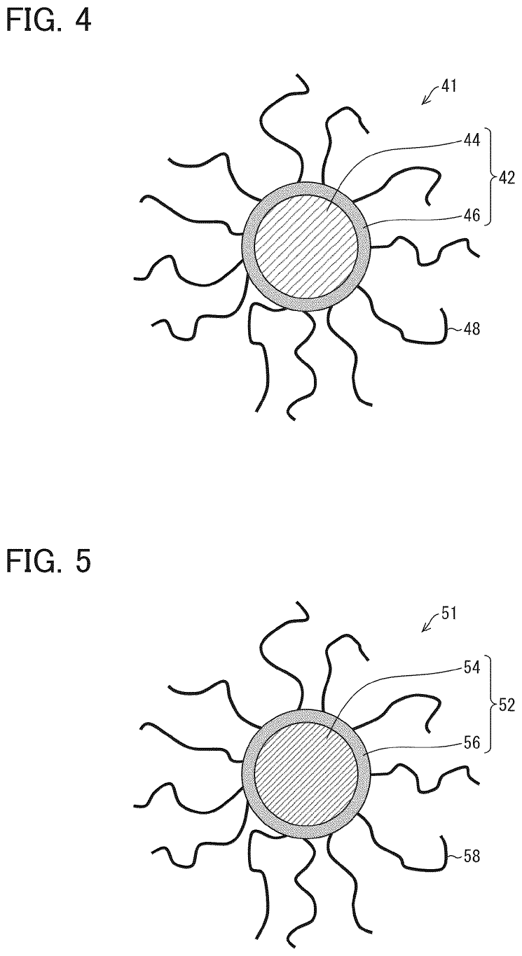

FIG. 4 schematically illustrates an example configuration of a P-type quantum dot 41 illustrated in FIG. 3. FIG. 5 schematically illustrates an example configuration of an N-type quantum dot 51 illustrated in FIG. 3.

This section details an instance where a first nanocrystal 42 and a second nanocrystal 52 fall under a core-shell type. Other than the foregoing, the first nanocrystal 42 and the second nanocrystal 52 each may fall under other types, such as a core type without a shell, or a core-multi-shell type with a shell composed of multiple layers.

As illustrated in FIG. 4, the P-type quantum dot 41 includes the first nanocrystal 42 and first ligands 48 coordinating with the first nanocrystal 42. The first nanocrystal 42 includes a first core 44 and a first shell 46 covering the surface of the first core 44. As illustrated in FIG. 5, the N-type quantum dot 51 likewise includes the second nanocrystal 52 and second ligands 58 coordinating with the second nanocrystal 52. The second nanocrystal 52 includes a second core 54 and a second shell 56 covering the surface of the second core 45.

Unless otherwise specified, the Fermi level and forbidden band of the P-type quantum dot 41 are a Fermi level 44f of the first core 44, and a forbidden band 44B of the same. Further, unless otherwise specified, the Fermi level and forbidden band of the N-type quantum dot 51 are a Fermi level 54f of the second core 54, and a forbidden band 54B of the same.

The first core 44 and the second core 54 have their average particle diameters equal to each other. Here, an average particle diameter is a particle diameter's designed value, or a particle diameter's median value measured through a dynamic light scattering method. Further, the designed value may be used for one of these two average particle diameters, and the median value may be used for the other; alternatively, the designed value may be used for both; alternatively, the median value may be used for both. Further, the wording “equal average particle diameters” includes not only an instance where the two average particle diameters coincide, but also an instance where smaller one of the two average particle diameters is 80% or greater and less than 100% of the larger average particle diameter. Further, the dispersion in the particle diameter of each of the first core 44 and second core 54 preferably stands at 20% or smaller of the corresponding average particle diameter.

The first core 44 and the second core 54 are made of materials containing mutually identical main ingredients. Usable examples of the main ingredients include the following: a group IV semiconductor material, including C and Si; a group III-V semiconductor material, including InP; a group II-VI semiconductor material, including CdSe, CdS, ZnSe and ZnS; a ternary semiconductor material, including InGaP and ZnTeSe; and a quaternary semiconductor material, including CuInGaSe (CIGS).

The first shell 46 and the second shell 56 have their average thicknesses equal to each other. Here, an average thickness is a thickness's designed value, or a difference in particle diameter's median value between the first core 44 and first nanocrystal 42 measured through a dynamic light scattering method as well as a difference in particle diameter's median value between the second core 54 and second nanocrystal 52 measured through the dynamic light scattering method. Further, the designed value may be used for one of these two average thicknesses, and the median value may be used for the other; alternatively, the designed value may be used for both; alternatively, the median value may be used for both. Further, the wording “equal average thicknesses” includes not only an instance where the two average thicknesses coincide, but also an instance where smaller one of the two average thicknesses is 80% or greater and less than 100% of the larger average thickness. Further, the dispersion in the thickness of each of the first shell 46 and second shell 56 preferably stands at 20% or smaller of the corresponding average thickness.

The first shell 46 and the second shell 56 may be made of materials containing main ingredients identical to or different from each other. Usable examples of the main ingredients include GaP, a group II-VI semiconductor material, including CdS and ZnSe, and a ternary semiconductor material, including ZnSeS.

### Ligand

The first ligands 48 separate the first nanocrystals 42 from each other to avoid the first nanocrystals 42 excited from deactivation without light emission. The first ligands are preferably long enough for deactivation avoidance. To be specific, the first ligands are preferably 1 nm or greater long. Likewise, the second ligands 58 are preferably 1 nm or greater long.

On the other hand, if the first ligands 48 are too long, the first nanocrystals 42 are separated from each other too much, thereby raising the turn-on voltage of the light-emitting element ES. The first ligands are thus not preferably too long. To be specific, the first ligands are preferably 10 nm or smaller long, are more desirably 5 nm or smaller long and are further preferably 2 nm or smaller long. Likewise, the second ligands 58 are preferably 10 nm or smaller long, are more desirably 5 nm or smaller long and are further preferably 2 nm or smaller long.

Ligand length may be calculated from bonding length and bonding angle, may be obtained from a molecular dynamics simulation or other simulations or may be actually measured through microwave spectrometry or other methods.

The first ligands 48 and the second ligands 58 each include a functional group for coordinating with the first nanocrystal 42 and the second nanocrystal 52. The functional group is selected from the group consisting of a thiol group, a carboxyl group, and an amino group.

The first ligand 48 may have an alkyl chain in order to adjust its length. The alkyl chain desirably has 12 or less carbon atoms. Further, the alkyl chain is preferably, within the first ligand 48, located away from the functional group for the first ligand 48 to coordinate with the first nanocrystal 42. Likewise, the second ligand 58 may have an alkyl chain, and the alkyl chain preferably has 12 or less carbon atoms and is preferably, within the second ligand 58, located away from the functional group.

The first ligand 48 may be composed of a single kind of compound, or a plurality of kinds of compound. Likewise, the second ligand 58 may be composed of a single kind of compound, or a plurality of kinds of compound.

### Adjustment of Core's Fermi Level

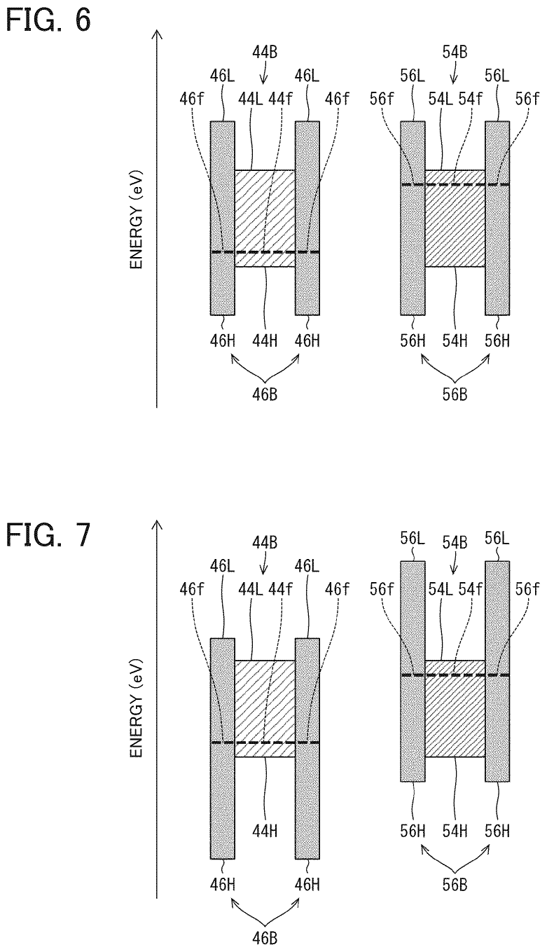

FIG. 6 schematically illustrates example forbidden bands 44B and 46B as well as example Fermi levels 44f and 46f of the first core 44 and first shell 46 illustrated in FIG. 4, and example forbidden bands 54B and 56B as well as example Fermi levels 54f and 56f of the second core 54 and second shell 56 illustrated in FIG. 5.

FIG. 7 schematically illustrates other example forbidden bands 44B and 46B as well as other example Fermi levels 44f and 46f of the first core 44 and first shell 46 illustrated in FIG. 4, and other example forbidden bands 54B and 56B as well as other example Fermi levels 54f and 56f of the second core 54 and second shell 56 illustrated in FIG. 5.

The Fermi level 44f of the first core 44 is located between a conduction band level 44L of the first core 44 and a valence band level 44H of the same, that is, within the forbidden band 44B, as illustrated in FIG. 6 and FIG. 7. Furthermore, the Fermi level 44f of the first core 44 is adjusted so as to be located closer to the valence band level 44H than to the center of the forbidden band 44B. As a result, the P-type quantum dot 41 has less electrons in the conduction band level, and more holes in the valence band level than an I-type quantum dot, the Fermi level of which is located at the center of its forbidden band. An I-type quantum dot has electrons in the conduction band level, and holes in the valence band level by substantially the same amount at room temperature. That is, the P-type quantum dot 41 at room temperature has more holes in the valence band level than electrons in the conduction band level.

Holes can thus move within the P-type light-emitting layer 40 more easily than they can within an I-type light-emitting layer containing I-type quantum dots by moving from the valence band of one first core 44 to the valence band of another first core 44. On the other hand, electrons are difficult to move within the P-type light-emitting layer 40. That is, hole mobility is higher than electron mobility. As a result, the P-type light-emitting layer 40 exhibits lower electron transportability and higher hole transportability than an I-type light-emitting layer. An I-type light-emitting layer exhibits electron transportability and hole transportability substantially equally at room temperature. That is, the P-type light-emitting layer 40 exhibits higher hole transportability than electron transportability.

In contrast, the Fermi level 54f of the second core 54 is located between a valence band level 54H of the second core 54 and a conduction band level 54L of the same, that is, within the forbidden band 54B, as illustrated in FIG. 6 and FIG. 7. Furthermore, the Fermi level 54f of the second core 54 is adjusted so as to be located closer to the conduction band level 54L than to the center of the forbidden band 54B. As a result, the N-type quantum dot 51 has less holes in the valence band level, and more electrons in the conduction band level than an I-type quantum dot, the Fermi level of which is located at the center of its forbidden band. An I-type quantum dot has electrons in the conduction band level, and holes in the valence band level by substantially the same amount at room temperature. That is, the N-type quantum dot 51 at room temperature has more electrons in the conduction band level than holes in the valence band level.

Electrons can thus move within the N-type light-emitting layer 50 easily by moving from the conduction band of one second core 54 to the conduction band of another second core 54. On the other hand, holes in contrast are difficult to move within the N-type light-emitting layer 50. That is, electron mobility is higher than hole mobility. As a result, the N-type light-emitting layer 50 exhibits lower hole transportability and higher electron transportability than an I-type light-emitting layer. An I-type light-emitting layer exhibits electron transportability and hole transportability substantially equally at room temperature. That is, the N-type light-emitting layer 50 exhibits higher electron transportability than hole transportability.

As described above, the Fermi level 44f of the first core 44 is located close to the valence band level 44H, and the Fermi level 54f of the second core 54 is located close to the conduction band level 54L. The Fermi level 54f of the second core 54 is consequently closer to a vacuum energy level than the Fermi level 44f of the first core 44 is.

The following details various examples of how to adjust the Fermi levels 44f and 54f of the first core 44 and second core 54.

### Adjustment Using Ligand

A first adjustment method uses the first ligands 48 and second ligands 58 made of mutually different materials. To be specific, an electron-withdrawing ligand is used for the first ligands 48, and an electron-donating ligand is used for the second ligands 58.

To simplify description, the following describes an instance where the first core 44 and the second core 54 are composed only of mutually identical intrinsic semiconductors, and where the first shell 46 and the second shell 56 are composed only of mutually identical intrinsic semiconductors.

As illustrated in FIG. 4, the first ligands 48 coordinate with the first nanocrystal 42. The Fermi level 46f of the first shell 46 is thus affected by the dipole moment of the first ligands 48. Moreover, the Fermi level 44f of the first core 44 is also affected by the dipole moment of the first ligands 48 through the first shell 46. The dipole moments of various compounds can be estimated easily using first-principles calculation.

The electron-withdrawing ligand includes at least one compound selected from the group consisting of compounds with their dipole moments not standing at zero, and with the positive directions of their dipole moments being toward a functional group coordinating with a nanocrystal. The electron-withdrawing ligand includes, for instance, at least one compound selected from the group consisting of compounds expressed by Structural Formula (1) below.

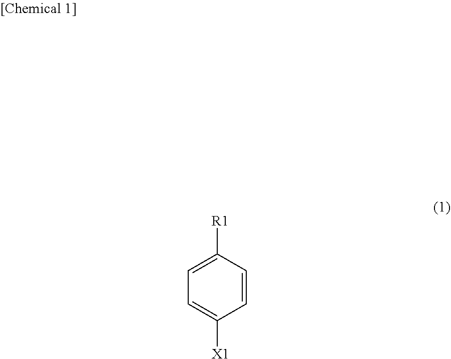

Here, X1 is a functional group coordinating with a nanocrystal, such as the first nanocrystal 42, and denotes a thiol group, a carboxyl group or an amino group. Alternatively, X1 denotes a thiolate anion, a carboxylate anion or an aminolate anion. The thiolate anion, the carboxylate anion, and the aminolate anion are respectively a functional group with a thiol group negatively charged, a functional group with a carboxyl group negatively charged, and a functional group with an amino group negatively charged.

Here, R1 includes at least one selected from a triazole skeleton, a triazine skeleton, a thiophene skeleton, a furan skeleton, a thiazole skeleton, an oxazole skeleton, an oxadiazole skeleton and a thiothiazole skeleton.

The group consisting of the compounds expressed by Structural Formula (1) includes, for instance, the group consisting of compounds expressed by Structural Formulas (2) to (6) below.

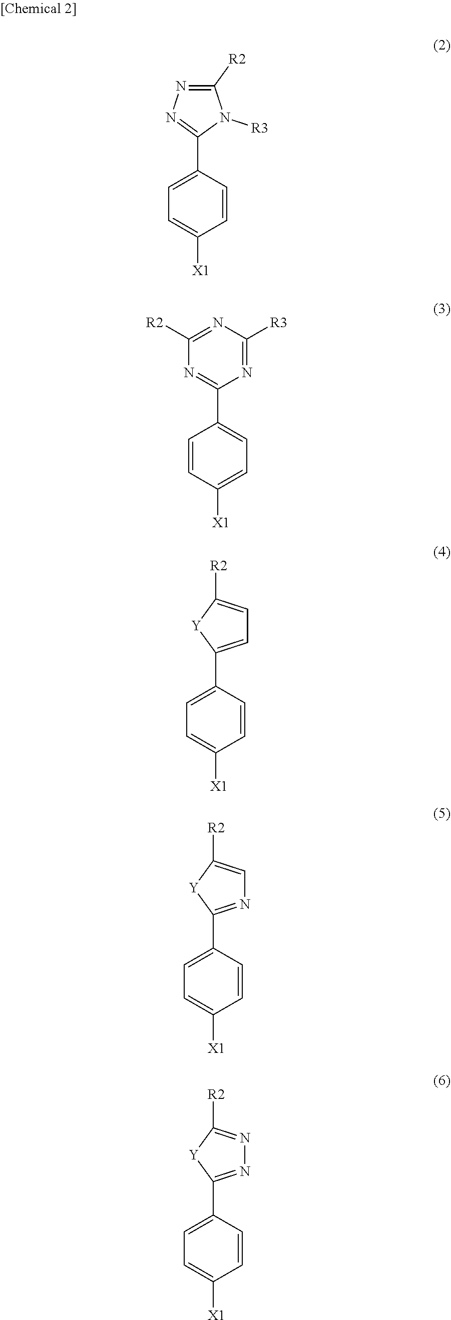

Here, X1 may be identical or different between Structural Formulas (2) to (6).

Here, R2 and R3 may be identical to or different from each other. R2 and R3 each independently denote a hydrogen atom, a substituted or non-substituted alkyl group having 1 to 12 carbon atoms, or a substituted or non-substituted phenyl group. Among them, a non-substituted phenyl group or biphenyl group is used suitably. Y denotes an O-atom or a S-atom.

When the first ligands 48 exhibit an electron-withdrawing capability, electrons flow out from the first core 44 and first shell 46 to the first ligands 48. As a result, the Fermi level 44f of the first core 44 is located closer to the valence band level 44H than to the center of the forbidden band 44B, and the Fermi level 46f of the first shell 46 is located closer to the valence band level 46H than to the center of the forbidden band 46B, as illustrated in FIG. 6.

As illustrated in FIG. 5, the second ligands 58 coordinate with the second nanocrystal 52. The Fermi level 56f of the second shell 56 is thus affected by the dipole moment of the second ligands 58; as a result, the Fermi level 54f of the second core 54 can be affected by the dipole moment of the second ligands 58.

The electron-donating ligand includes at least one compound selected from the group consisting of compounds with their dipole moments not standing at zero, and with the negative directions of their dipole moments being toward a functional group coordinating with a nanocrystal. The electron-donating ligand includes, for instance, at least one compound selected from the group consisting of compounds expressed by Structural Formula (7) below.

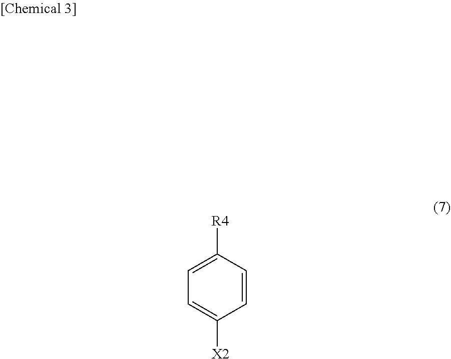

Here, X2 is a functional group coordinating with a nanocrystal, such as the second nanocrystal 52, and denotes a thiol group, a carboxyl group or an amino group, or X2 denotes an ammonium ion, or X2 denotes a thiolate anion, a carboxylate anion or an aminolate anion.

Here, R4 includes at least one selected from a carbazole skeleton, an acridine skeleton, a phenoxazine skeleton and a phenazine skeleton and has a nitrogen-containing aromatic ring. R4 is a nitrogen atom forming a nitrogen-containing aromatic ring and joins with a benzene ring, which is expressed by Structural Formula (7) above.

The group consisting of the compounds expressed by Structural Formula (7) includes, for instance, the group consisting of compounds expressed by Structural Formulas (8) to (11) below.

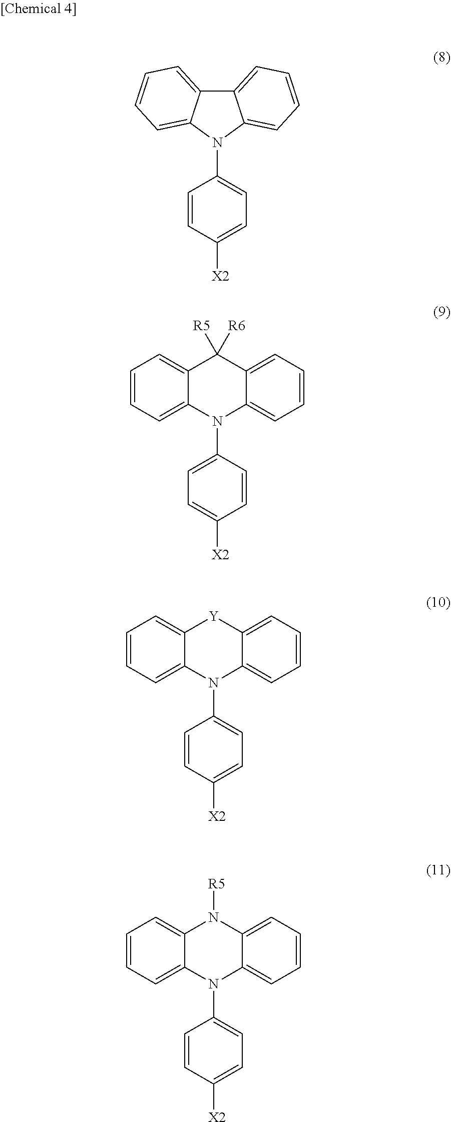

Here, X2 may be identical or different between Structural Formulas (8) to (11).

Here, R5 and R6 may be identical to or different from each other. R5 and R6 each independently denote a hydrogen atom, a substituted or non-substituted alkyl group having 1 to 12 carbon atoms, or a substituted or non-substituted phenyl group. Among them, a non-substituted phenyl group or biphenyl group is used suitably.

When the second ligands 58 exhibit an electron-donating capability, electrons flow from the second ligands 58 into the second shell 56 and second core 54. As a result, the Fermi level 54f of the second core 54 is located closer to the conduction band level 54L than to the center of the forbidden band 54B, and the Fermi level 56f of the second shell 56 is located closer to the conduction band level 56L than to the center of the forbidden band 56B, as illustrated in FIG. 6.

### Adjustment Using Core's Dope Ingredient

A second adjustment method uses the first core 44 and second core 54 containing mutually different dope ingredients. To be specific, the first core 44 contains an acceptor as its dope ingredient, and the second core 54 contains a donor as its dope ingredient.

To simplify description, the following describes an instance where the main ingredients of the first core 44 and second core 54 are composed of mutually identical intrinsic semiconductors, where the first shell 46 and the second shell 56 are composed only of mutually identical intrinsic semiconductors, and where the first ligand 48 and the second ligand 58 are composed of electrically neutral ligands.

The electrically neutral ligands include at least one compound selected from the group consisting of compounds with their dipole moments standing at zero or close to zero. The electrically neutral ligands include, for instance, at least one compound selected from the group consisting of compounds expressed by Structural Formulas (12) to (13) below.

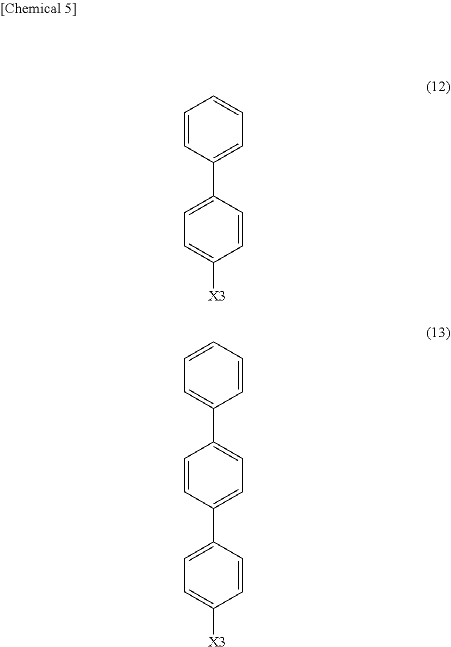

Here, X3 is a functional group coordinating with a nanocrystal, such as the first nanocrystal 42 or the second nanocrystal 52, and each independently denotes a thiol group, a carboxyl group or an amino group, or X3 each independently denotes a thiolate anion, a carboxylate anion or an aminolate anion.

The acceptor withdraws electrons from the intrinsic semiconductor, so that the intrinsic semiconductor changes into a positive semiconductor. The doner donates electrons to the intrinsic semiconductor, so that the intrinsic semiconductor changes into a negative semiconductor. Consequently, the Fermi level 44f of the first core 44 is close to the valence band level 44H, and the Fermi level 54f of the second core 54 is close to the conduction band level 54L, as illustrated in FIG. 6.

The acceptor is a group III element, such as B, when the main ingredient of the first core 44 is, for instance, a group IV semiconductor material, including C and Si. Further, the acceptor is a group II element, such as Zn, when the main ingredient of the first core 44 is, for instance, a group III-V semiconductor material, such as InP. Further, the acceptor is a group I element, such as Li, and a group V element, including N, P and As, when the main ingredient of the first core 44 is, for instance, a group II-VI semiconductor material, including CdSe, CdS, ZnSe and ZnS. Further, the acceptor is Zn or Mg when the main ingredient of the first core 44 is, for instance, InGaP. Further, acceptor addition is not necessary when the main ingredient of the first core 44 is, for instance, CIGS, because CIGS alone functions as a positive semiconductor.

The donor is a group V element, such as P, when the main ingredient of the second core 54 is, for instance, a group IV semiconductor material. Further, the donor is a group VI element, including Se and S, when the main ingredient of the second core 54 is, for instance, a group III-V semiconductor material. Further, the donor is a group VII element, including Cl and I, and a group III element, including Al and Ga, when the main ingredient of the second core 54 is, for instance, a group II-IV semiconductor material. Further, the donor is Sn when the main ingredient of the second core 54 is, for instance, InGaP. Further, the donor is Cd when the main ingredient of the second core 54 is, for instance, CIGS.

An excessive amount of acceptor or donor with respect to the main ingredient lowers the mobility of holes or electrons. It is hence preferable that the amount-of-substance ratio of the acceptor in the first core 44 and the amount-of-substance ratio of the donor in the second core 54 each stand at 1 to 10% inclusive.

### Adjustment Using Shell Material

A third adjustment method uses the first shell 46 and second shell 56 made of mutually different materials. To be specific, a material selection is made for the first shell 46 in such a manner that the Fermi level of a material that constitutes the first shell 46 is located close to the valence band level with respect to the Fermi level of the main ingredient of the first core 44. Moreover, a material selection is made for the second shell 56 in such a manner that the Fermi level of a material that constitutes the second shell 56 is located close to the conduction band level with respect to the Fermi level of the main ingredient of the second core 54.

To simplify description, the following describes an instance where the first core 44 and the second core 54 are composed only of mutually identical intrinsic semiconductors, and where the first ligand 48 and the second ligand 58 are composed only of electrically neutral ligands identical to each other.

As illustrated in FIG. 4, the first core 44 is covered with the first shell 46. The Fermi level 44f of the first core 44 is thus affected by the band structure of the first shell 46, particularly by the Fermi level 46f As earlier described, the Fermi level 44f of the first core 44 is close to the valence band level 44H, as illustrated in FIG. 7, when the Fermi level of the material of the first shell 46 is located close to the valence band level with respect to the Fermi level of the material of the first core 44.

As illustrated in FIG. 5, the second core 54 is covered with the second shell 56. The Fermi level 54f of the second core 54 is thus affected by the band structure of the second shell 56, particularly by the Fermi level 56f As earlier described, the Fermi level 54f of the second core 54 is close to the conduction band level 54L, as illustrated in FIG. 7, when the Fermi level of the material of the second shell 56 is located close to the valence band level with respect to the Fermi level of the material of the second core 54.

The main ingredient of the first shell 46 and the main ingredient of the second shell 56 may be materials identical to or different from each other. The first shell 46 preferably contains an acceptor as its dope ingredient, and the second shell 56 preferably contains a donor as its dope ingredient.

Other than the foregoing methods, the Fermi levels 44f and 54f of the first core 44 and second core 54 may be adjusted by any method or adjusted in combination with a plurality of methods. For instance, this adjustment may be made in combination with all the foregoing methods. In this case, (i) an electron-withdrawing ligand is used for the first ligands 48, and an electron-donating ligand is used for the second ligands 58; in addition, (ii) the main ingredient of the first core 44 and the main ingredient of the second core 54 are made of mutually identical materials; in addition, (iii) the first core 44 contains an acceptor as its dope ingredient, and the second core 54 contains a donor as its dope ingredient; in addition, (iv) the first shell 46 is formed of a material having a low Fermi level, and the second shell 56 is formed of a material having a high Fermi level.

### Band Structure of Active Layer

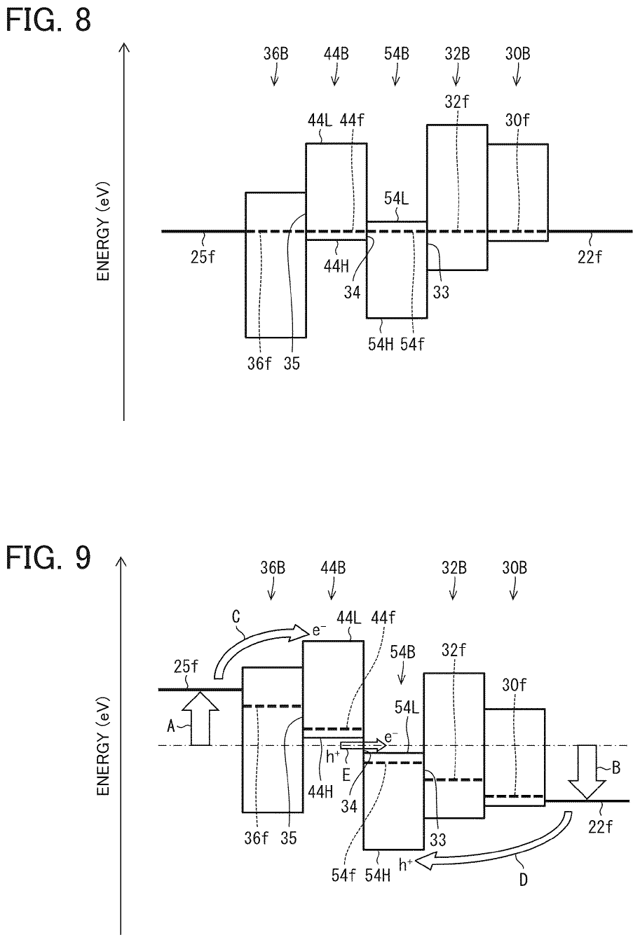

FIG. 8 schematically illustrates example Fermi levels 22f, 30f, 32f, 54f, 44f, 36f and 25f and example forbidden bands 30B, 32B, 54B, 44B and 36B of the anode 22, hole injection layer 30, hole transport layer 32, second core 54, first core 44, electron transport layer 36 and cathode 25 at the time when the light-emitting element ES illustrated in FIG. 3 does not emit light.

FIG. 9 schematically illustrates the Fermi levels 22f, 30f, 32f, 54f, 44f, 36f and 25f and forbidden bands 30B, 32B, 54B, 44B and 36B of the anode 22, hole injection layer 30, hole transport layer 32, second core 54, first core 44, electron transport layer 36 and cathode 25 at the time when the light-emitting element ES illustrated in FIG. 3 emits light.

It is noted that to be exact, a bend and a depletion layer are produced in the band structure by the effect of joining. To understand the disclosure deeply, FIG. 8 and FIG. 9 are illustrated simply.

As illustrated in FIG. 8, the Fermi levels 22f and 25f of the anode 22 and cathode 25 coincide with each other when the light-emitting element ES does not emit light. The Fermi levels 30f, 32f, 54f, 44f and 36f of the hole injection layer 30, hole transport layer 32, second core 54, first core 44 and electron transport layer 36 thus coincide with the Fermi levels 22f and 25f of the anode 22 and cathode 25.

As illustrated in FIG. 9, when the light-emitting element ES emits light, voltage denoted by Arrow B is applied to the anode 22, and voltage denoted by Arrow A is applied to the cathode 25. This produces a driving electric field for moving holes from the anode 22 to the cathode 25, and for moving electrons from the cathode 25 to the anode 22.

The holes injected from the anode 22 move to the valence bands of the second cores 54 via the hole injection layer 30 and hole transport layer 32, as illustrated in Arrow D in FIG. 9, in accordance with such a driving electric field. The holes, which are, as earlier described, difficult to move within the N-type light-emitting layer 50, then accumulate in the valence bands of the second cores 54 of the N-type quantum dots 51 located near a boundary surface 33 between the hole transport layer 32 and N-type light-emitting layer 50.

Likewise, the electrons injected from the cathode 25 move to the conduction bands of the first cores 44 via the electron transport layer 36, as illustrated in Arrow C in FIG. 9. The electrons, which are, as earlier described, difficult to move within the P-type light-emitting layer 40, then accumulate in the conduction bands of the first cores 44 of the P-type quantum dots 41 located near a boundary surface 35 between the electron transport layer 36 and P-type light-emitting layer 40.

Furthermore, the electrons in the valence bands of the first cores 44 move over a boundary surface 34 between the P-type light-emitting layer 40 and N-type light-emitting layer 50 and over a nearby energy barrier and are then pulled out into the conduction bands of the second cores 54, as illustrated in Arrow E in FIG. 9, in accordance with the driving electric field. This generates holes in the valence bands of the first cores 44. That is, the P-type light-emitting layer 40 and N-type light-emitting layer 50 in a pair function as a carrier generation layer.

The pulled-out electrons move within the N-type light-emitting layer 50, from the side near the P-type light-emitting layer 40 toward the side near the hole transport layer 32 in accordance with the driving electric field. Moreover, the electrons and holes recombine together in the second cores 54 of the N-type quantum dots 51 located near the boundary surface 33 between the N-type light-emitting layer 50 and hole transport layer 32, and the N-type quantum dots 51 are thus excited to emit light.

Likewise, the generated holes move within the P-type light-emitting layer 40, from the side near the N-type light-emitting layer 50 toward the side near the electron transport layer 36 in accordance with the driving electric field. Moreover, the electrons and holes recombine together in the first cores 44 of the P-type quantum dots 41 located near the boundary surface 35 between the P-type light-emitting layer 40 and electron transport layer 36, and the P-type quantum dots 41 are thus excited to emit light.

Consequently, injecting a pair of a hole and an electron can excite a single first nanocrystal 42 and a single second nanocrystal 52, thus possibly causing light emission twice in total. The P-type light-emitting layer 40 preferably has a thickness with which electrons are difficult to pass by a tunnel effect, in order to excite the first nanocrystal 42. For instance, the thickness of the P-type light-emitting layer 40 is preferably equal to or larger than the diameter of the P-type quantum dot 41 (including the thicknesses of the first ligands 48) and more desirably stands at 5 nm or greater. Likewise, the N-type light-emitting layer 50 preferably has a thickness with which electrons are difficult to pass by a tunnel effect, in order to excite the second nanocrystal 52. For instance, the thickness of the N-type light-emitting layer 50 is equal to or larger than the diameter of the N-type quantum dot 51 (including the thicknesses of the second ligands 58) and more desirably stands at 5 nm or greater. On the other hand, the thicknesses of the P-type light-emitting layer 40 and N-type light-emitting layer 50 each preferably stand at 50 20 nm or smaller and each more desirably stand at 20 nm or smaller, in order to lower the turn-on voltage of the light-emitting element ES.

The electron pull-out from the second core 54 to the first core 44, denoted by Arrow E, is preferably easy in order to lower the turn-on voltage of the light-emitting element ES. It is particularly preferable that the electrons at the valence band level 44H of the first core 44 pass through the energy barrier due to a tunnel effect to be thus pulled out into the conduction band level 54L of the second core 54. Accordingly, the energy difference between the end of the valence band level 44H of the first core 44 and the end of the conduction band level 54L of the second core 54 is preferably small during the non-light emission illustrated in FIG. 8.

The energy difference between the end of the valence band level 44H of the first core 44 (i.e., the upper end of the valence band of the first core 44) and the end of the conduction band level 54L of the second core 54 (i.e., the lower end of the conduction band of the second core 54) during the non-light emission is equal to the sum of (i) the energy difference between the end of the valence band level 44H of the first core 44 and the Fermi level 44f of the same, and (ii) the energy difference between the end of the conduction band level 54L of the second core 54 and the Fermi level 54f of the same. It is thus preferable that the energy difference between the Fermi level 44f of the first core 44 and the end of the valence band level 44H of the same be small, and that the energy difference between the Fermi level 54f of the second core 54 and the end of the conduction band level 54L of the same be small. To be specific, the sum of (i) the energy difference between the end of the valence band level 44H of the first core 44 and the Fermi level 44f of the same, and (ii) the energy difference between the end of the conduction band level 54L of the second core 54 and the Fermi level 54f of the same preferably stands at 1.0 eV or smaller, more desirably stands at 0.5 eV or smaller and is preferably close to 0 eV as much as possible.

The electrons in the valence band of the first core 44 more desirably pass through the energy barrier due to a tunnel effect to be thus pulled out into the conduction band of the second core 54, as denoted by Arrow E in FIG. 9, in order to facilitate the electron pull-out denoted by Arrow E. It is thus preferable that during the light emission illustrated in FIG. 9, the energy value at the end of the valence band level 44H of the first core 44 coincide with the energy value of the end of the conduction band level 54L of the second core 54, or the valence band level 44H of the first core 44 overlap the conduction band level 54L of the second core 54.

### Coloration of Light-Emitting Element

The following describes the coloration of the light-emitting element ES.

As earlier described, the first core 44 of the P-type quantum dot 41, included in the P-type light-emitting layer 40, and the second core 54 of the N-type quantum dot 51, included in the N-type light-emitting layer 50, are made of materials containing mutually identical main ingredients. The emission wavelength band of the P-type light-emitting layer 40 that results from electric-field light emission and the emission wavelength band of the N-type light-emitting layer 50 that results from electric-field light emission are hence similar to each other. To be specific, the emission wavelength bands of the P-type light-emitting layer 40 and N-type light-emitting layer 50 have an overlap, and the P-type light-emitting layer 40 and the N-type light-emitting layer 50 each have an emission peak wavelength in a portion where their emission wavelength bands overlap each other. The color of emitted light from the P-type light-emitting layer 40 and the color of emitted light from the N-type light-emitting layer 50 are thus similar to each other.

The difference in emission peak wavelength between the P-type light-emitting layer 40 and N-type light-emitting layer 50 is normally small. The color of emitted light from the P-type light-emitting layer 40 and the color of emitted light from the N-type light-emitting layer 50 are hence substantially identical to each other. The difference in emission peak wavelength between the P-type light-emitting layer 40 and N-type light-emitting layer 50 preferably stands at 20 nm or smaller and more desirably stands at 10 nm or smaller.

The color of emitted light from the P-type light-emitting layer 40 and the color of emitted light from the N-type light-emitting layer 50 are substantially the same as described, and thus, each light-emitting element ES emits light of substantially the same color as the colors of emitted light from the corresponding P-type light-emitting layer 40 and corresponding N-type light-emitting layer 50.

### Action and Effect

A known tandem QLED requires an additional carrier generation layer to be provided between its light-emitting layers. This produces a large distance between its anode and cathode, thereby unfortunately raising the turn-on voltage of this light-emitting element. In addition, this involves many films to be formed, thereby increasing the number of process steps necessary for the manufacture, thus unfortunately lowering manufacturing yield and reliability.

In contrast to this, the P-type light-emitting layer 40 and N-type light-emitting layer 50 in a pair function as a carrier generation layer in the configuration of the present disclosure. This eliminates the need for separately forming an additional carrier generation layer between the P-type light-emitting layer 40 and the N-type light-emitting layer 50. The distance between the anode 22 and cathode 25 according to the present disclosure is thus smaller than before, thereby enabling the turn-on voltage of the light-emitting element ES to be lowered. In addition, the number of films to be formed is small, reducing the number of process steps necessary for the manufacture, thus improving manufacturing yield and reliability.

Further, as earlier described, injecting a pair of a hole and an electron can cause light emission twice in total in the configuration of the present disclosure. The light-emitting element ES according to the present disclosure can consequently improve external quantum efficiency (EQE), like a known tandem QLED.

### Second Embodiment

The following describes another embodiment of the disclosure. It is noted that for convenience in description, components having the same functions as the components described in the foregoing embodiment will be denoted by the same signs, and their description will not be repeated.

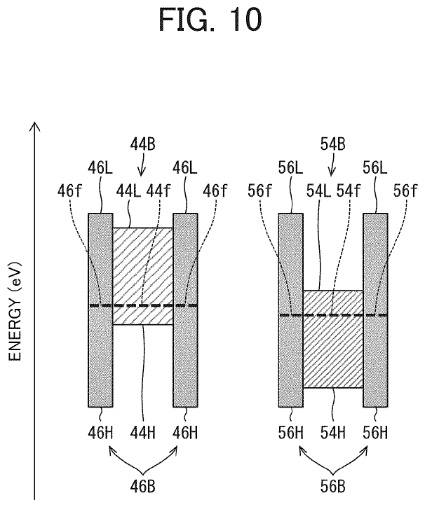

FIG. 10 schematically illustrates examples of the forbidden bands 44B and 46B and Fermi levels 44f and 46f of the first core 44 and first shell 46 according to a second embodiment, and examples of the forbidden bands 54B and 56B and Fermi levels 54f and 56f of the second core 54 and second shell 56 according to the second embodiment.

The light-emitting element ES according to the second embodiment has the same configuration as the light-emitting element ES according to the first embodiment with the exception that the main ingredients of the first core 44 and second core 54 are made of mutually different materials, and that their average particle diameters may be different or equal. To be specific, a material selection is made for the first core 44 in such a manner that the Fermi level of a material that constitutes the first core 44 according to the second embodiment is located close to the conduction band level with respect to the Fermi level of the material of the first shell 46. Moreover, a material selection is made for the second core 54 in such a manner that the Fermi level of a material that constitutes the second core 54 is located close to the valence band level with respect to the Fermi level of the material of the second shell 56. In other words, the Fermi level of the material of the first shell 46 is located close to the valence band level with respect to the Fermi level of the main ingredient of the first core 44, and the Fermi level of the material of the second shell 56 is located close to the conduction band level with respect to the Fermi level of the main ingredient of the second core 54.

To simplify description, the following describes an instance where the first shell 46 and the second shell 56 are composed of mutually identical intrinsic semiconductors, and where the first ligand 48 and the second ligand 58 are composed of electrically neutral ligands.

As earlier described with reference to FIG. 4, the Fermi level 44f of the first core 44 is affected by the Fermi level 46f of the first shell 46. As earlier described, the Fermi level 44f of the first core 44 is close to the valence band level 44H, as illustrated in FIG. 10, when the Fermi level of the material of the first shell 46 is located close to the valence band level with respect to the Fermi level of the material of the first core 44.

As earlier described with reference to FIG. 5, the Fermi level 54f of the second core 54 is affected by the Fermi level 56f of the second shell 56. As earlier described, the Fermi level 54f of the second core 54 is close to the conduction band level 54L, as illustrated in FIG. 10, when the Fermi level of the material of the second shell 56 is located close to the valence band level with respect to the Fermi level of the material of the second core 54.

Other than the foregoing methods, the Fermi levels 44f and 54f may be adjusted in combination with a plurality of methods. For instance, this adjustment may be made in combination with one or more of the methods described in the first embodiment and the method described in the second embodiment.

### Carrier Generation Probability

To simplify description, the following describes an instance where the width of the forbidden band 44B of the first core 44 and the width of the forbidden band 54B of the second core 54 are equal to each other.

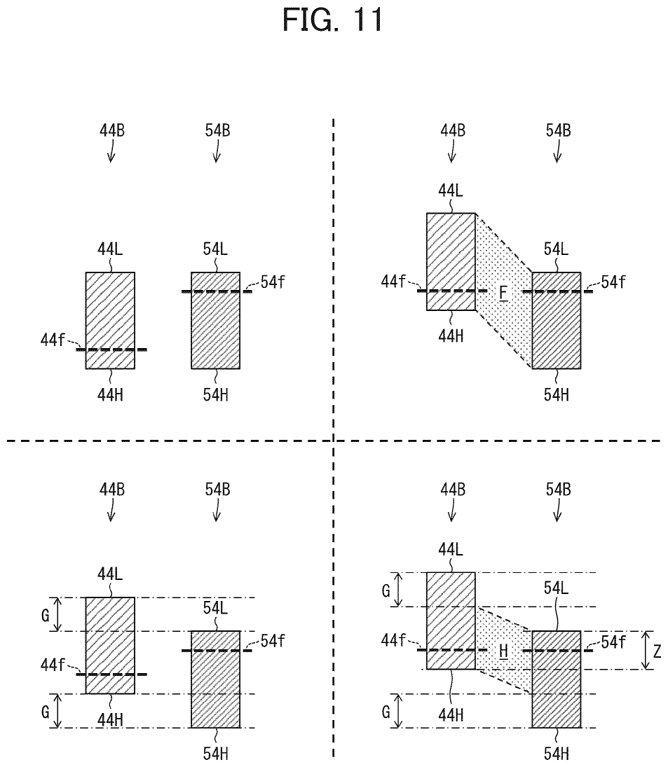

FIG. 11 schematically illustrates the difference in carrier generation probability between the first embodiment and second embodiment. FIG. 11 illustrates, on the upper side, the forbidden bands 44B and 54B of the first core 44 and second core 54 in the first embodiment; on the lower side, the forbidden bands 44B and 54B of the first core 44 and second core 54 in the second embodiment; on the left side, the forbidden bands 44B and 54B of the first core 44 and second core 54 with the P-type light-emitting layer 40 and N-type light-emitting layer 50 being not joined together; and on the right side, the forbidden bands 44B and 54B of the first core 44 and second core 54 with the P-type light-emitting layer 40 and N-type light-emitting layer 50 being joined together.

As illustrated on the upper left in FIG. 11, the energy difference between the end of the valence band level 44H of the first core 44 and the end of the valence band level 54H of the second core 54 (or between the ends of the conduction band levels 44L and 54L) stands at zero or almost zero when the P-type light-emitting layer 40 and the N-type light-emitting layer 50 are not joined together in the first embodiment. In contrast, as illustrated on the lower left in FIG. 11, the energy difference between the end of the valence band level 44H of the first core 44 and the end of the valence band level 54H of the second core 54 stands at not zero, but G (eV) when the P-type light-emitting layer 40 and the N-type light-emitting layer 50 are not joined together in the second embodiment.

A carrier generation probability P1 in the boundary surface 34 in the first embodiment and a carrier generation probability P2 in the boundary surface 34 in the second embodiment, when compared, are proportional to the ratio between the reciprocal of an area F of the parallelogram illustrated on the upper right in FIG. 11 and the reciprocal of an area H of the parallelogram illustrated on the lower right in FIG. 11. That is, P1/P2∝H/F is established.

As such, the configuration according to the second embodiment can improve the carrier generation probability further than the configuration according to the first embodiment. Further, the area H is preferably small in order to improve the carrier generation probability. Here, the area H depends on an energy difference Z between the end of the valence band level 44H of the first core 44 and the end of the conduction band level 54L of the second core 54 in the joined state in the second embodiment. The energy difference Z is thus preferably small. To be specific, the energy difference Z preferably stands at 2 eV or smaller, more desirably stands at 1 eV or smaller and further preferably stands at 0.5 eV or smaller.

An energy difference G is preferably large in order to reduce the energy difference Z.

Furthermore, to facilitate the electron pull-out denoted by Arrow E in FIG. 9, the ionization energy of the first core 44 is preferably smaller than the ionization energy of the second core 54 (alternatively, the electron affinity of the first core 44 is preferably smaller than the electron affinity of the second core 54) in the not-yet-joined state illustrated on the lower left in FIG. 11.

The Fermi levels of CdSe, CdS, ZnTe and ZnSe are located closer to their valence bands than to the centers of their forbidden bands in their natural states, where they are not affected by a dope ingredient and joining. Hence, to improve the carrier generation probability, the main ingredient of the first core 44 of the P-type quantum dot 41 of the P-type light-emitting layer 40 preferably contains at least one semiconductor material selected from the group consisting of CdSe, CdS, ZnTe and ZnSe.

The Fermi levels of InP, CdTe and Pb Se are located closer to their valence bands than to the centers of their forbidden bands in their natural states, where they are not affected by a dope ingredient and joining. Hence, to improve the carrier generation probability, the main ingredient of the second core 54 of the N-type quantum dot 51 of the N-type light-emitting layer 50 preferably contains at least one semiconductor material selected from the group consisting of InP, CdTe, Pb Se, ZnS and ZnTeSe.

### Action and Effect

In the light-emitting element ES according to the first embodiment, the difference in emission peak wavelength between the P-type light-emitting layer 40 and N-type light-emitting layer 50 is small normally but is difficult to render zero. This is because that the width of the forbidden band 44B of the first core 44 and the width of the forbidden band 54B of the second core 54 are different from each other as a result of the fact that the main ingredients of the first core 44 and second core 54 are identical to each other, and as a result of such an adjustment that the Fermi levels 44f and 54f are different from each other.

In contrast to this, in the light-emitting element ES according to the second embodiment, the main ingredients of the first core 44 and second core 54 are different from each other. Accordingly, a selection of main ingredients for the first core 44 and second core 54 as well as a selection of a method and degree of adjusting the Fermi levels 44f and 54f can further reduce the difference in emission peak wavelength between the P-type light-emitting layer 40 and N-type light-emitting layer 50 and can also render the difference zero. The configuration according to the second embodiment thus enables the colors of emitted light from the P-type light-emitting layer 40 and N-type light-emitting layer 50 to be the same.

Further, in the configuration according to the second embodiment, a quantum dot containing no heavy metal, including Cd and Pb, as its core's main ingredient can be used for at least one of the P-type quantum dot 41 and N-type quantum dot 51. This can reduce the volume of heavy metal within the light-emitting element ES. Further, using a quantum dot containing heavy metal for one of them, and a quantum dot containing no heavy metal for the other can keep the coloration of the light-emitting element ES favorable while reducing the volume of heavy metal within the light-emitting element ES. Examples of the quantum dot containing heavy metal include a Cd-based quantum dot containing a compound, including CdSe, CdS and CdTe, as its core's main ingredient, and a Pb-based quantum dot containing a compound, including Pb Se and PbS, as its core's main ingredient. Examples of the quantum dot containing no heavy metal include an In-based quantum dot containing a compound, such as InP, as its core's main ingredient, a Zn-based quantum dot containing a compound, including ZnTe and ZnSe, as its core's main ingredient, a Si-based quantum dot, and a C-based quantum dot.

A quantum dot containing CdSe, CdTe, Pb Se or InP as its core's main ingredient can emit red, green or blue light. A quantum dot containing CdS, ZnTe or ZnSe as its core's main ingredient can emit green or blue light.

As such, for the light-emitting element ES that emits red light, the main ingredient of the first core 44 is preferably CdSe, and the main ingredient of the second core 54 is preferably InP. Further, for the light-emitting element ES that emits green light, the main ingredient of the first core 44 is preferably CdSe or CdS, and the main ingredient of the second core 54 is preferably InP; in addition, the main ingredient of the first core 44 is preferably ZnTe or ZnSe, and the main ingredient of the second core 54 is preferably CdTe or PbSe. Further, for the light-emitting element ES that emits blue light, the main ingredient of the first core 44 is preferably ZnTe, ZnSe or InP, and the main ingredient of the second core 54 is preferably CdTe or Pb Se.

### Third Embodiment

The following describes another embodiment of the disclosure. It is noted that for convenience in description, components having the same functions as the components described in the foregoing embodiments will be denoted by the same signs, and their description will not be repeated.

The light-emitting element ES according to a third embodiment has the same configuration as the light-emitting elements ES according to the first and second embodiments with the exception that the P-type light-emitting layer 40 and the N-type light-emitting layer 50 emit different colors of light.

In the first and second embodiments, the width of the forbidden band 44B of the first core 44 (i.e., the energy difference between the end of the valence band level 44H and the end of the conduction band level 44L) and the width of the forbidden band 54B of the second core 54 (i.e., the energy difference between the end of the valence band level 54H and the end of the conduction band level 54L) are the same or almost the same. In the third embodiment by contrast, the forbidden bands 44B and 54B of the first core 44 and second core 54 are different from each other.

Any method may be used to establish different widths between the forbidden band 44B of the first core 44 and the forbidden band 54B of the second core 54. For instance, the average particle diameter of the first core 44 and the average particle diameter of the second core 54 may be different. Additionally or alternatively, the first nanocrystal 42 and the second nanocrystal 52 may be formed of mutually different materials for instance.

The widths of the forbidden bands 44B and 54B are different as described above; consequently, the P-type light-emitting layer 40 and the N-type light-emitting layer 50 emit different colors of light in the light-emitting element ES according to the third embodiment. Moreover, the light-emitting element ES according to the third embodiment exhibits a mixed color with the color of emitted light from the P-type light-emitting layer 40 and the color of emitted light from the N-type light-emitting layer 50 being mixed together. The mixed color and each color of emitted light may be any color. For instance, setting the color of emitted light from the P-type light-emitting layer 40 at blue, and the color of emitted light from the N-type light-emitting layer 50 at red so that the mixed color is white enables the light-emitting element ES to emit white light.

### Band Structure of Active Layer

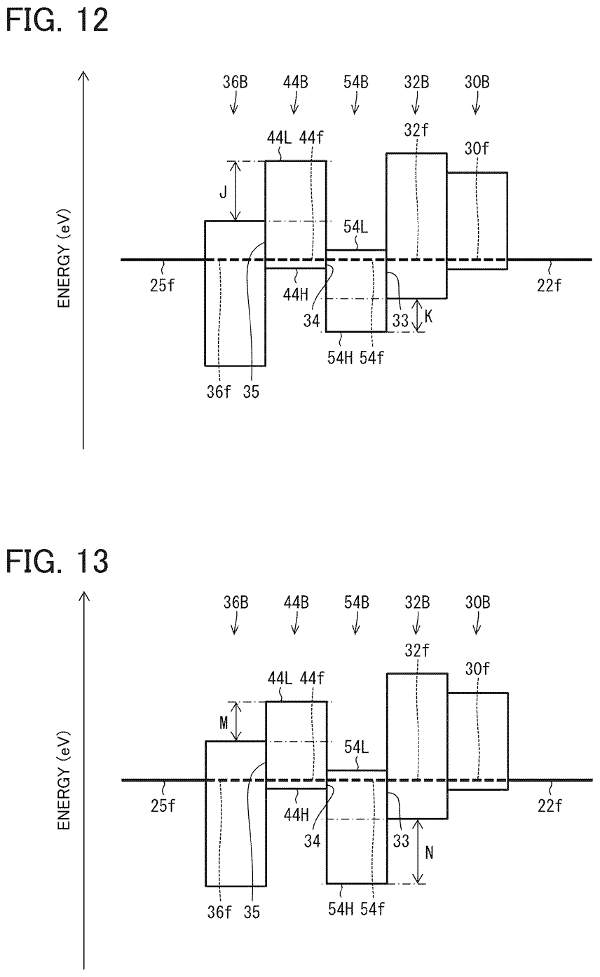

FIG. 12 schematically illustrates examples of the Fermi levels 22f, 30f, 32f, 54f, 44f, 36f and 25f and forbidden bands 30B, 32B, 54B, 44B and 36B of the anode 22, hole injection layer 30, hole transport layer 32, second core 54, first core 44, electron transport layer 36 and cathode 25 at the time when the light-emitting element ES according to the third embodiment does not emit light.

FIG. 13 schematically illustrates other examples of the Fermi levels 22f, 30f, 32f, 54f, 44f, 36f and 25f and forbidden bands 30B, 32B, 54B, 44B and 36B of the anode 22, hole injection layer 30, hole transport layer 32, second core 54, first core 44, electron transport layer 36 and cathode 25 at the time when the light-emitting element ES according to the third embodiment does not emit light.

The light-emitting element ES according to the third embodiment includes a configuration where the forbidden band 44B of the first core 44 is wider than the forbidden band 54B of the second core 54, as illustrated in FIG. 12, and a configuration where the forbidden band 44B of the first core 44 is narrower than the forbidden band 54B of the second core 54, as illustrated in FIG. 13.

To simplify description, the following describes an instance where the example configurations illustrated in FIG. 12 and FIG. 13 satisfy the following four conditions:

The width of the forbidden band 44B of the first core 44 in FIG. 12 is equal to the width of the forbidden band 54B of the second core 54 in FIG. 13;

The width of the forbidden band 54B of the second core 54 in FIG. 12 is equal to the width of the forbidden band 44B of the first core 44 in FIG. 13;

The energy difference between the Fermi level 44f of the first core 44 and the end of the valence band level 44H of the same in FIG. 12 is equal to the energy difference between the Fermi level 44f of the first core 44 and the end of the valence band level 44H of the same in FIG. 13; and

The energy difference between the Fermi level 54f of the second core 54 and the end of the conduction band level 54L of the same in FIG. 12 is equal to the energy difference between the Fermi level 54f of the second core 54 and the end of the conduction band level 54L of the same in FIG. 13.

An energy barrier J, which requires electrons that move from the conduction band of the electron transport layer 36 to the conduction band of the first core 44 to go over in the configuration illustrated in FIG. 12, is larger than an energy barrier M, which requires these electrons to go over in the configuration illustrated in FIG. 13. That is, J>M is established. The electron mobility from the cathode 25 to the first core 44 in the configuration in FIG. 12 is lower than that in the configuration in FIG. 13.

Further, an energy barrier K, which requires holes that move from the valence band of the hole transport layer 32 to the valence band of the second core 54 to go over in the configuration in FIG. 12, is smaller than an energy barrier N, which requires these holes to go over in the configuration in FIG. 13. That is, K<N is established. The hole mobility from the anode 22 to the second core 54 in the configuration in FIG. 12 is higher than that in the configuration in FIG. 13.

As such, the configuration in FIG. 12 involves a demerit and a merit: low electron mobility and high hole mobility. On the other hand, the configuration in FIG. 13 involves a merit and a demerit: high electron mobility and low hole mobility. Since electron mobility tends to be higher than hole mobility, the merit, high hole mobility, is more important than the demerit, low electron mobility. The configuration where the forbidden band 44B of the first core 44 illustrated in FIG. 12 is wider than the forbidden band 54B of the second core 54 in the same thus enables the turn-on voltage to be lower than that in the configuration illustrated in FIG. 13.

When the forbidden band 44B of the first core 44 is wider than the forbidden band 54B of the second core 54 as described above, the emission peak wavelength of the P-type light-emitting layer 40 is shorter than the emission peak wavelength of the N-type light-emitting layer 50. It is thus preferable to design the light-emitting element ES in such a manner that the P-type light-emitting layer 40 emits shorter-wavelength light, and that the N-type light-emitting layer 50 emits longer-wavelength light.

### Fourth Embodiment

The following describes another embodiment of the disclosure. It is noted that for convenience in description, components having the same functions as the components described in the foregoing embodiments will be denoted by the same signs, and their description will not be repeated.

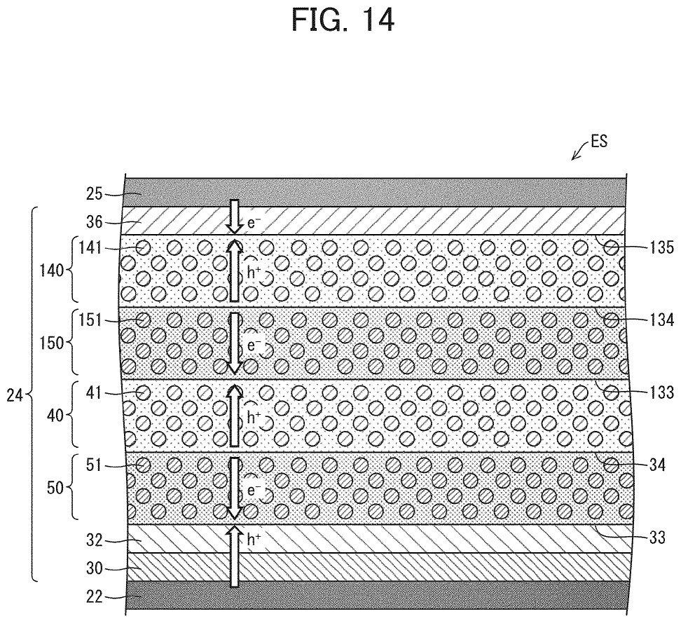

FIG. 14 is a schematic sectional view of an example stacked structure of the light-emitting element ES according to a fourth embodiment.

The light-emitting element ES according to the fourth embodiment has the same configuration as the light-emitting elements ES according to the first to third embodiments with the exception that this light-emitting element ES further includes a second P-type light-emitting layer (P-type quantum-dot light-emitting layer) 140 and a second N-type light-emitting layer (N-type quantum-dot light-emitting layer) 150.

As illustrated in FIG. 14, the active layer 14 according to the fourth embodiment includes the second P-type light-emitting layer 140 and the second N-type light-emitting layer 150 between the electron transport layer 36 and the first P-type light-emitting layer 40 in the stated order from the cathode 25.

The configuration and function of each of the second P-type light-emitting layer 140 and second N-type light-emitting layer 150 are similar to those of each of the first P-type light-emitting layer 40 and first N-type light-emitting layer 50. The second P-type light-emitting layer 140 and the second N-type light-emitting layer 150 constitute a pair of light-emitting layers.

As such, when the light-emitting element ES emits light, electrons in the valence band of a third core of a second P-type dot 141 within the second P-type light-emitting layer 140 move over a boundary surface 134 between the second P-type light-emitting layer 140 and second N-type light-emitting layer 150, and over a nearby energy barrier to be thus pulled out into the conduction band of a fourth core of a second N-type quantum dot 151 within the second N-type light-emitting layer 150. This generates holes in the valence band of the third core of the second P-type dot 141. That is, the second P-type light-emitting layer 140 and second N-type light-emitting layer 150 in a pair function as a carrier generation layer.

As a result, injecting a pair of a hole and an electron can excite a single first P-type quantum dot 41 or second N-type quantum dot 151, a single first N-type quantum dot 51, and a single second P-type dot 141, thus causing light emission three times in total.

To be specific, firstly, electrons and holes recombine together in the first P-type quantum dots 41 or second N-type quantum dots 151 located near a boundary surface 133, thus exciting the first P-type quantum dots 41 or second N-type quantum dots 151 to thus emit light. Secondly, electrons and holes recombine together in the first N-type quantum dots 51 located near the boundary surface 33, thus exciting the first N-type quantum dots 51 to thus emit light. Thirdly, electrons and holes recombine together in the second P-type dots 141 located near a boundary surface 135, thus exciting the second P-type dots 141 to thus emit light.

It is noted that the light-emitting element ES according to the fourth embodiment may include three or more pairs of a P-type light-emitting layer (P-type quantum-dot light-emitting layer) and an N-type light-emitting layer (N-type quantum-dot light-emitting layer).

### Modification

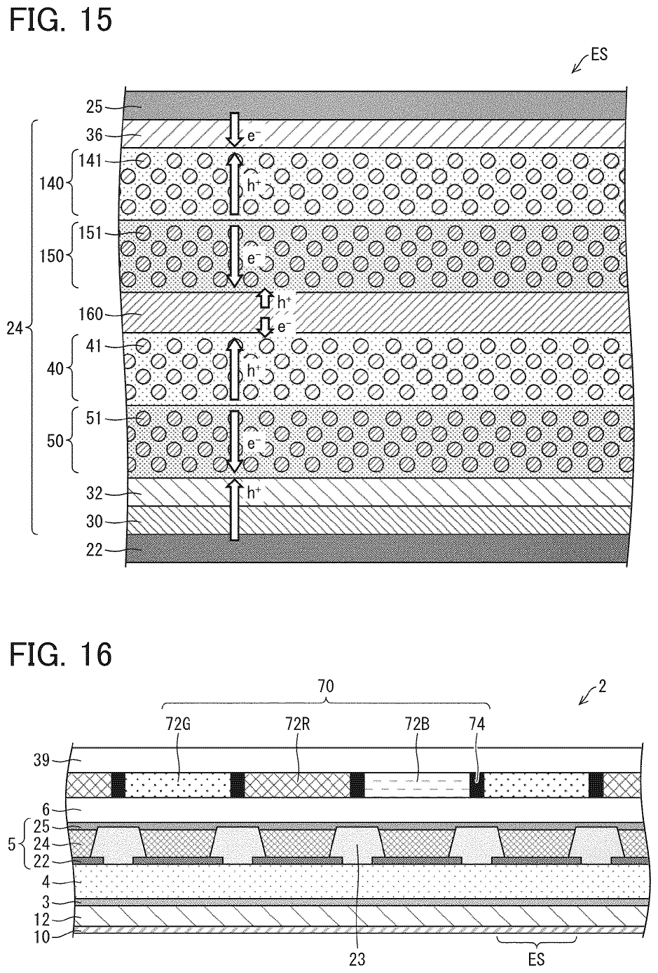

FIG. 15 is a schematic sectional view of another example stacked structure of the light-emitting element ES according to the fourth embodiment.

As illustrated in FIG. 15, the active layer 24 according to the fourth embodiment may further include a carrier generation layer 160 between the P-type light-emitting layer 40 and the

N-type light-emitting layer 150. In this case, injecting a pair of a hole and an electron can excite a single first P-type quantum dot 41, a single first N-type quantum dot 51, a single second P-type dot 141, and a single second N-type quantum dot 151, thus causing light emission four times in total.

### Fifth Embodiment

The following describes another embodiment of the disclosure. It is noted that for convenience in description, components having the same functions as the components described in the foregoing embodiments will be denoted by the same signs, and their description will not be repeated.

FIG. 16 is a schematic sectional view of an example configuration of the display region of the display device 2 according to a fifth embodiment.

The display device (light-emitting device) 2 according to the fifth embodiment has the same configuration as the display device 2 according to the first embodiment with the exception that this display device 2 further includes a color filter 70 between the sealing layer 6 and the function film 39.

The color filter 70 includes a red region 72R that allows red light to pass, a green region 72G that allows green light to pass, a blue region 72B that allows blue light to pass, and a light blocking region 74 that blocks light. The color filter 70 is placed in such a manner that the red region 72R, the green region 72G and the blue region 72B are in one-to-one correspondence with the light-emitting elements ES.

It is noted that this placement is not limited to that illustrated in FIG. 16; the color filter needs to be located closer to the light-emitting surface than the active layer 24 is.

### Action and Effect

In the configurations according to the first to fourth embodiments, the display device 2 needs to include a light-emitting element ES that emits red light, a light-emitting element ES that emits green light, and a light-emitting element ES that emits blue light in order to perform multi-color display. That is, to perform multi-color display, the display device 2 needs to include light-emitting elements ES having mutually different configurations.

The configuration according to the fifth embodiment enables the display device 2 to perform multi-color display using the color filter 70 while enabling a plurality of light-emitting elements ES included in the display device 2 to have mutually identical configurations. For instance, the configuration enables all the plurality of light-emitting elements ES to be formed so as to exhibit white. This can simplify the manufacturing process steps and can improve yield rate.

### Sixth Embodiment

The following describes another embodiment of the disclosure. It is noted that for convenience in description, components having the same functions as the components described in the foregoing embodiments will be denoted by the same signs, and their description will not be repeated.

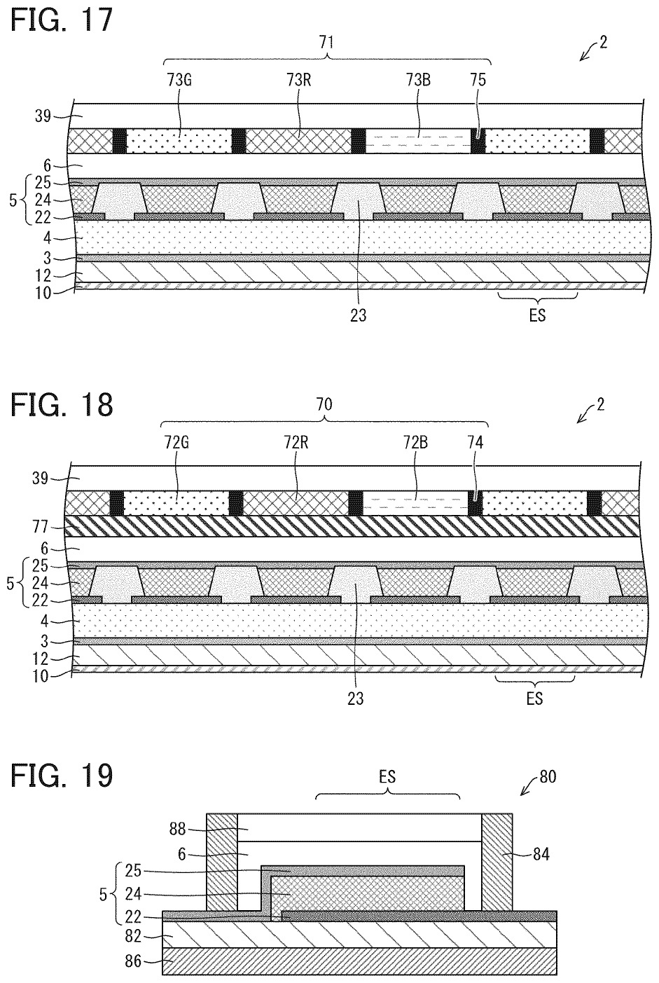

FIG. 17 is a schematic sectional view of an example configuration of the display region of the display device 2 according to a sixth embodiment.

The display device 2 according to the sixth embodiment has the same configuration as the display device 2 according to the first embodiment with the exception that this display device 2 further includes a wavelength conversion layer 71 between the sealing layer 6 and the function film 39.

The wavelength conversion layer 71 includes a red region 73R that can convert light emitted from the light-emitting element ES into red light, a green region 73G that can convert the light into green light, a blue region 73B that can convert the light into blue light, and a light blocking region 73 that blocks the light. The wavelength conversion layer 71 is placed in such a manner that the red region 73R, the green region 73G and the blue region 73B are in one-to-one correspondence with the light-emitting elements ES.

It is noted that this placement is not limited to that illustrated in FIG. 17; the wavelength conversion layer 71 needs to be located closer to the light-emitting surface than the active layer 24 is. It is also noted that the configuration of the wavelength conversion layer 71 is not limited to that illustrated in FIG. 17; the wavelength conversion layer 71 needs to perform wavelength conversion on the light emitted from the light-emitting element ES in part or in whole in such a manner that the light's wavelength after passage through the wavelength conversion layer 71 is shorter than the light's wavelength before passage.

### Action and Effect

The configuration according to the sixth embodiment enables the display device 2 to perform multi-color display using the wavelength conversion layer 71 while enabling a plurality of light-emitting elements ES included in the display device 2 to have mutually identical configurations. For instance, the configuration enables all the plurality of light-emitting elements ES to be formed so as to exhibit ultraviolet, violet or blue. This can simplify the manufacturing process steps and can improve yield rate.

It is noted that the wavelength conversion layer 71 does not have to include the blue region 73B when the light-emitting element ES exhibits blue. It is also noted that the light-emitting element ES may further include the color filter 70 according to the fifth embodiment.

### Seventh Embodiment

The following describes another embodiment of the disclosure. It is noted that for convenience in description, components having the same functions as the components described in the foregoing embodiments will be denoted by the same signs, and their description will not be repeated.

FIG. 18 is a schematic sectional view of an example configuration of the display region of the display device 2 according to a seventh embodiment.

The display device 2 according to the seventh embodiment has the same configuration as the display device 2 according to the fifth embodiment with the exception that this display device 2 further includes a wavelength conversion layer 77 between the sealing layer 6 and the function film 39.

The wavelength conversion layer 77 can perform wavelength conversion on part of light emitted from the light-emitting element ES in such a manner that the light's wavelength after passage through the wavelength conversion layer 77 is shorter than the light's wavelength before passage. This extends the wavelength range of light that can be emitted from the display device 2 toward the shorter wavelength.

It is noted that the placement of the wavelength conversion layer 77 is not limited to that illustrated in FIG. 18; the wavelength conversion layer 77 needs to be located between the active layer 24 and the color filter 70. It is also noted that the display device 2 may include the wavelength conversion layer 77 without the color filter 70.

### Action and Effect

The configuration according to the seventh embodiment extends the wavelength range of light that can be emitted from the display device 2 toward the shorter wavelength. This can enhance the color rendering of the display device 2.

### Eighth Embodiment

The following describes another embodiment of the disclosure. It is noted that for convenience in description, components having the same functions as the components described in the foregoing embodiments will be denoted by the same signs, and their description will not be repeated.

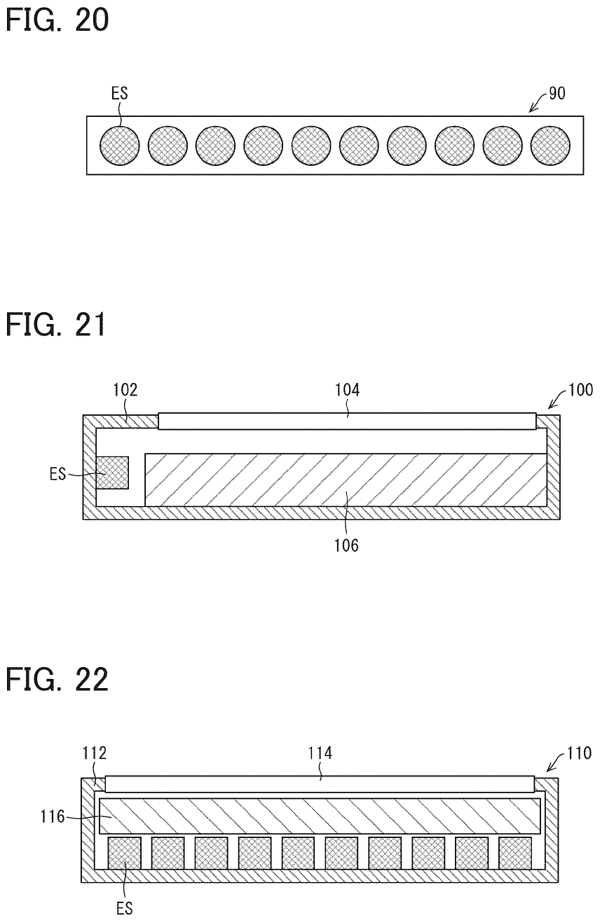

FIG. 19, FIG. 20, FIG. 21 and FIG. 22 each schematically illustrate an example configuration of a lighting device according to an eight embodiment.

As illustrated in FIG. 19, a light-emitting chip (point light source, lighting device, light-emitting device) 80 includes the following: the light-emitting element ES; outer packages 86 and 88 for protecting the light-emitting element ES; and an optical window 88 that allows light emitted by the light-emitting element ES to pass.

The light-emitting element ES is small, and thus, the light-emitting chip 80 functions as a point light source.

As illustrated in FIG. 20, a lighting device (linear light source, light-emitting device) 90 includes the following: a plurality of light-emitting elements ES; an outer package for protecting the light-emitting elements ES; and the optical window 88 that allows light emitted by the light-emitting elements ES to pass.

The plurality of light-emitting elements ES are arranged in a straight line. The lighting device 90 thus functions as a linear light source.

As illustrated in FIG. 21, a lighting device (planar light source, light-emitting device) 100 includes the following: a plurality of light-emitting elements ES arranged in a straight line; a light guide plate 106 that spreads light emitted by the plurality of light-emitting elements ES in a planar manner; an outer package 102 for protecting the light-emitting elements ES and the light guide plate 106; and an optical window 104 that allows the light spread by the light guide plate 106 to pass.

The light emitted by the plurality of light-emitting elements ES is spread in a planar manner by light guide plate 106. The lighting device 100 thus functions as a planar light source.

As illustrated in FIG. 22, a lighting device (planar light source, light-emitting device) 110 includes the following: a plurality of light-emitting elements ES arrange in matrix; a diffuser plate 116 that uniformly diffuses light emitted by the plurality of light-emitting elements ES; an outer package 112 for protecting the light-emitting elements ES and the diffuser plate 116; and an optical window 114 that allows the light diffused by the diffuser plate 116 to pass.

The light emitted by the plurality of light-emitting elements ES is diffused uniformly by the diffuser plate 116. The lighting device 110 thus functions as a planar light source.

Although not shown, the lighting devices 80, 90, 100 and 110 may further include any one or more of the color filter 70, wavelength conversion layer 71 and wavelength conversion layer 77.

### Summary

A light-emitting element (ES) according to a first aspect of the disclosure includes the following: a negative electrode (25); a positive electrode (22); and at least one pair of light-emitting layers formed between the negative electrode (25) and the positive electrode (22), wherein the at least one pair of light-emitting layers includes, in the stated order from the cathode (25), a P-type quantum-dot light-emitting layer (40, 140) and an N-type quantum-dot light-emitting layer (50, 150) adjacent to each other.

In the foregoing configuration, voltage application between the negative electrode and positive electrode generates carriers in the boundary surface between the P-type quantum-dot light-emitting layer and N-type quantum-dot light-emitting layer. That is, holes are generated in the valence band of the P-type quantum-dot light-emitting layer, and electrons are generated in the conduction band of the N-type quantum-dot light-emitting layer. This causes electrons injected from the negative electrode, and the holes generated in the valence band of the P-type quantum-dot light-emitting layer to recombine together and causes holes injected from the positive electrode, and the electrons generated in the conduction band of the N-type quantum-dot light-emitting layer to recombine together. As a result, the light-emitting element can output more than one photon using a single electron.

The foregoing configuration can thus offer a light-emitting element with high external quantum efficiency.

Further, the foregoing configuration eliminates the need for separately forming a layer for generating charge between the light-emitting layers, unlike a knowntandem light-emitting element, in order to output more than one photon from a single light-emitting element. The foregoing configuration enables more than one photon to be output from a single light-emitting element using less stacked layers than those in a knowntandem light-emitting element. This can reduce the thickness of the light-emitting element and can thus lower its turn-on voltage when compared with a knowntandem light-emitting element that outputs as many photons as this light-emitting element. Further, the number of process steps can be reduced, improving yield. This can offer a light-emitting element with higher reliability than before.

Further, the foregoing configuration enables more photons to be output than a knowntandem light-emitting element that is as thick as this light-emitting element. This can offer a light-emitting element with higher external quantum efficiency than before without increasing thickness from before.

The light-emitting element (ES) according to a second aspect of the disclosure may be configured, in the light-emitting element (ES) according to the first aspect, such that the P-type light-emitting layer includes a first quantum dot, such that the N-type quantum-dot light-emitting layer includes a second quantum dot, and such that the Fermi level of the second quantum dot is closer to a vacuum energy level than the Fermi level of the first quantum dot is.

The light-emitting element (ES) according to a third aspect of the disclosure may be configured, in the light-emitting element (ES) according to the first or second aspect, such that the P-type light-emitting layer includes a first quantum dot and exhibits a higher hole transportability than an electron transportability, and such that the N-type light-emitting layer includes a second quantum dot and exhibits a higher electron transportability than a hole transportability.

The light-emitting element (ES) according to a fourth aspect of the disclosure may be configured, in the light-emitting element (ES) according to any one of the first to third aspects, such that the P-type quantum-dot light-emitting layer includes a first quantum dot, and the hole mobility of the first quantum dot is higher than the electron mobility of the first quantum dot, and such that the N-type quantum-dot light-emitting layer includes a second quantum dot, and the electron mobility of the second quantum dot is higher than the hole mobility of the second quantum dot.

In any of the foregoing configurations, the P-type quantum-dot light-emitting layer behaves like a P-type semiconductor with regard to electrical conduction, and the N-type quantum-dot light-emitting layer behaves like an N-type semiconductor with regard to electrical conduction.

The light-emitting element (ES) according to a fifth aspect of the disclosure may be configured, in the light-emitting element (ES) according to any one of the first to fourth aspects, such that the P-type light-emitting layer includes a first quantum dot, and the first quantum dot includes a first core, such that the N-type light-emitting layer includes a second quantum dot, and the second quantum dot includes a second core, such that the ionization energy of the first core is smaller than the ionization energy of the second core, and such that the electron affinity of the first core is smaller than the electron affinity of the second core.

In the foregoing configuration, the P-type quantum-dot light-emitting layer behaves like a P-type semiconductor with regard to electrical conduction, and the N-type quantum-dot light-emitting layer behaves like an N-type semiconductor with regard to electrical conduction. Furthermore, electron pull-out from the valence band of the first core to the conduction band of the second core is easy in light emission.

The light-emitting element (ES) according to a sixth aspect of the disclosure may be configured, in the light-emitting element (ES) according to any one of the first to fifth aspects, such that the P-type light-emitting layer includes a first quantum dot, and the Fermi level of the first quantum dot (41, 141) is located closer to the valence band of the first quantum dot (41, 141) than to the center of the forbidden band of the first quantum dot, and such that the N-type light-emitting layer includes a second quantum dot, and the Fermi level of the second quantum dot (51, 151) is located closer to the conduction band of the second quantum dot (51, 151) than to the center of the forbidden band of the second quantum dot.

In the foregoing configuration, holes tend to be in the valence band of the first quantum dot, and electrons tend to be in the conduction band of the second quantum dot. Holes can thus move within the P-type quantum-dot light-emitting layer easily by moving from the valence band of one first core to the valence band of another first core. Likewise, electrons can move within the N-type quantum-dot light-emitting layer easily by moving from the conduction band of one second core to the conduction band of another second core. Thus, the P-type quantum-dot light-emitting layer behaves like a P-type semiconductor with regard to electrical conduction, and the N-type quantum-dot light-emitting layer behaves like an N-type semiconductor with regard to electrical conduction.

The light-emitting element (ES) according to a seventh aspect of the disclosure may be configured, in the light-emitting element (ES) according to the sixth aspect, such that the sum of the energy difference between the Fermi level of the first quantum dot (41, 141) and the upper end of the valence band of the first quantum dot, and the energy difference between the Fermi level of the second quantum dot (51, 151) and the lower end of the conduction band of the second quantum dot is 1.0 eV or smaller.

In the foregoing configuration, voltage application between the negative electrode and positive electrode tends to cause electrons to be pulled out from the valence band of the P-type quantum-dot light-emitting layer to the conduction band of the N-type quantum-dot light-emitting layer. Hence, carriers tend to be generated in the boundary surface between the P-type quantum-dot light-emitting layer and N-type quantum-dot light-emitting layer.

The light-emitting element (ES) according to an eighth aspect of the disclosure may be configured, in the light-emitting element (ES) according to the sixth or seventh aspect, such that the sum of the energy difference between the Fermi level of the first quantum dot (41, 141) and the upper end of the valence band of the first quantum dot, and the energy difference between the Fermi level of the second quantum dot (51, 151) and the lower end of the conduction band of the second quantum dot is 0.5 eV or smaller.

In the foregoing configuration, voltage application between the negative electrode and positive electrode tends to generate carriers further in the boundary surface between the P-type quantum-dot light-emitting layer and N-type quantum-dot light-emitting layer.

The light-emitting element (ES) according to a ninth aspect of the disclosure may be configured, in the light-emitting element (ES) according to any one of the second to eighth aspects, such that the first quantum dot (40, 140) includes a first nanocrystal (42) and a first ligand (48) coordinating with the first nanocrystal (42), such that the N-type quantum-dot light-emitting layer (50, 150) includes a second nanocrystal (52) and a second ligand (58) coordinating with the second nanocrystal (52), and such that the first ligand (48) and the second ligand (58) are formed of mutually different materials.

In the foregoing configuration, changing the ligand can obtain a P-type quantum-dot light-emitting layer and an N-type quantum-dot light-emitting layer, thereby offering a light-emitting element that includes the P-type quantum-dot light-emitting layer and the N-type quantum-dot light-emitting layer.

The light-emitting element (ES) according to a tenth aspect of the disclosure may be configured, in the light-emitting element (ES) according to the ninth aspect, such that the first ligand (48, 148) exhibits an electron-withdrawing capability, and such that the second ligand (58, 158) exhibits an electron-donating capability.

The light-emitting element (ES) according to an eleventh aspect of the disclosure may be configured, in the light-emitting element (ES) according to the tenth aspect, such that the negative direction of the dipole moment of the first ligand (48) is toward a functional group coordinating with the first nanocrystal (42), and such that the positive direction of the dipole moment of the second ligand (58) is toward a functional group coordinating with the second nanocrystal (52).

The light-emitting element (ES) according to a twelfth aspect of the disclosure may be configured, in the light-emitting element (ES) according to any one of the ninth to eleventh aspects, such that the first ligand (48) includes at least one compound selected from the group consisting of compounds expressed by the following structural formula (1), and such that the second ligand (58) includes at least one compound selected from the group consisting of compounds expressed by the following structural formula (7):

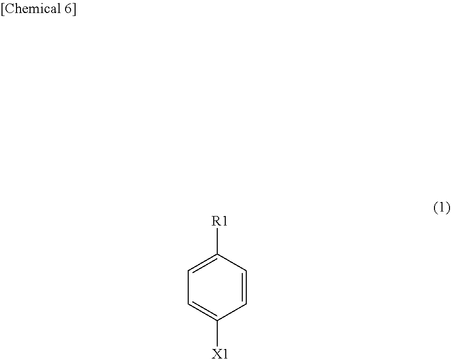

where X1 is a functional group coordinating with the first nanocrystal (42) and denotes a thiol group, a carboxyl group or an amino group, or X1 denotes a thiolate anion, a carboxylate anion or an aminolate anion, where R1 includes at least one selected from a triazole skeleton, a triazine skeleton, a thiophene skeleton, a furan skeleton, a thiazole skeleton, an oxazole skeleton, an oxadiazole skeleton and a thiothiazole skeleton, and

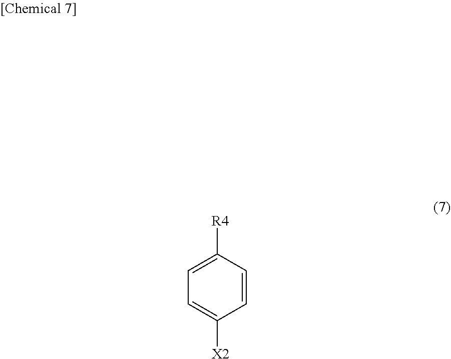

where X2 is a functional group coordinating with the second nanocrystal (52) and denotes a thiol group, a carboxyl group or an amino group, or X2 denotes an ammonium ion, or X2 denotes a thiolate anion, a carboxylate anion or an aminolate anion, where R4 includes at least one selected from a carbazole skeleton, an acridine skeleton, a phenoxazine skeleton and a phenazine skeleton and has a nitrogen-containing aromatic ring, where R4 is a nitrogen atom forming a nitrogen-containing aromatic ring and joins with a benzene ring expressed by the foregoing structural formula (7).

The light-emitting element (ES) according to a thirteenth aspect of the disclosure may be configured, in the light-emitting element (ES) according to the twelfth aspect, such that the at least one compound expressed by the structural formula (1) is at least one compound selected from the group consisting of compounds expressed by the following structural formulas (2) to (6), and such that the at least one compound expressed by the structural formula (7) is at least one compound selected from the group consisting of compounds expressed by the following structural formulas (8) to (11):

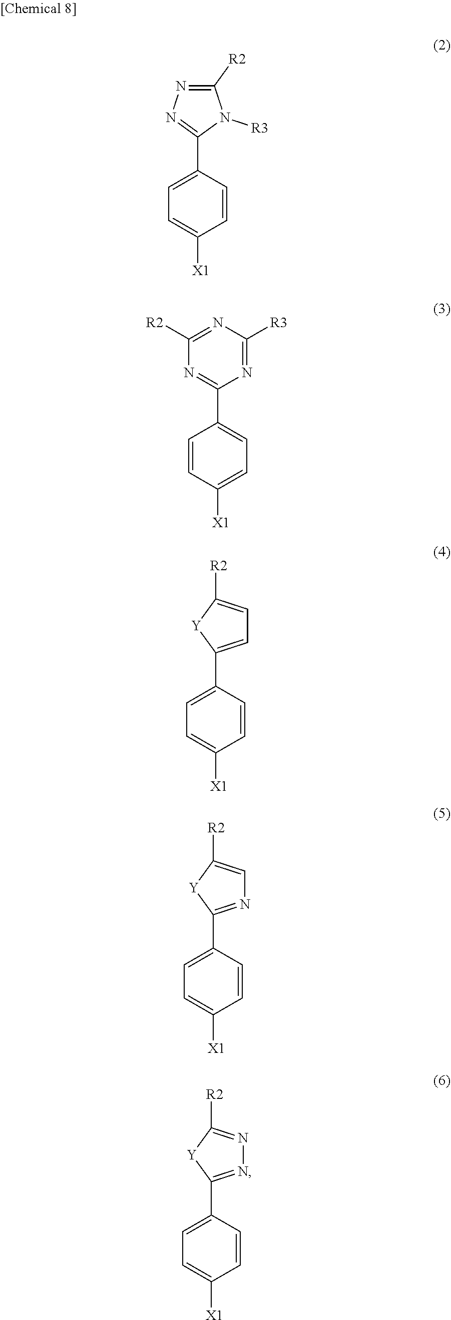

where X1 may be identical or different between the structural formulas, where R2 and R3 may be identical to or different from each other, where R2 and R3 each independently denote a hydrogen atom, a substituted or non-substituted alkyl group having 1 to 12 carbon atoms, or a substituted or non-substituted phenyl group, and

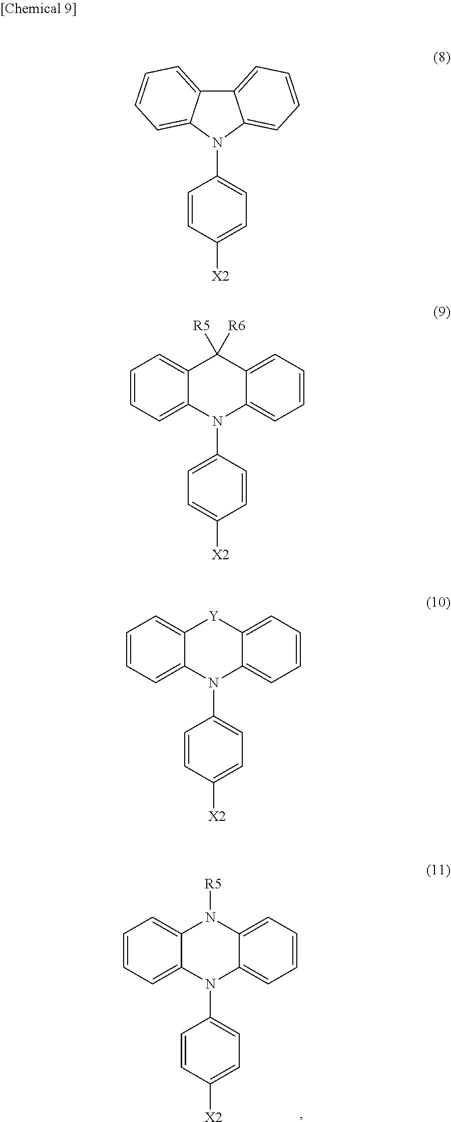

where X2 may be identical or different between the structural formulas, where R5 and R6 may be identical to or different from each other, where R5 and R6 each independently denote a hydrogen atom, a substituted or non-substituted alkyl group having 1 to 12 carbon atoms, or a substituted or non-substituted phenyl group.

The light-emitting element (ES) according to a fourteenth aspect of the disclosure may be configured, in the light-emitting element (ES) according to any one of the ninth to thirteenth aspects, such that the first ligand (48) and the second ligand (58) are 1 nm or greater long.

In the foregoing configuration, that the first ligand and the second ligand are 1 nm or greater long can avoid the first quantum dot and second quantum dot from deactivation.

The light-emitting element (ES) according to a fifteenth aspect of the disclosure may be configured, in the light-emitting element (ES) according to the fourteenth aspect, such that the first ligand (48) and the second ligand (58) are 10 nm or smaller long.

In the foregoing configuration, that the first ligand and the second ligand are 10 nm or smaller long can lower the turn-on voltage.

The light-emitting element (ES) according to a sixteenth aspect of the disclosure may be configured, in the light-emitting element (ES) according to the fifteenth aspect, such that the first ligand (48) and the second ligand (58) are 5 nm or smaller long.

In the foregoing configuration, that the first ligand and the second ligand are 5 nm or smaller long can lower the turn-on voltage further.

The light-emitting element (ES) according to a seventeenth aspect of the disclosure may be configured, in the light-emitting element (ES) according to the sixteenth aspect, such that the first ligand (48, 148) and the second ligand (58, 158) are 2 nm or smaller long.

In the foregoing configuration, that the first ligand and the second ligand are 2 nm or smaller long can lower the turn-on voltage further.

The light-emitting element (ES) according to an eighteenth aspect of the disclosure may be configured, in the light-emitting element (ES) according to any one of the second to seventeenth aspects, such that the first quantum dot (41, 141) includes a first core (44) containing an acceptor as a dope ingredient, and such that the second quantum dot (51, 151) includes a second core (54) containing a donor as a dope ingredient.

In the foregoing configuration, changing the core's dope ingredient can obtain a P-type quantum-dot light-emitting layer and an N-type quantum-dot light-emitting layer, thereby offering a light-emitting element that includes the P-type quantum-dot light-emitting layer and the N-type quantum-dot light-emitting layer.

The light-emitting element (ES) according to a nineteenth aspect of the disclosure may be configured, in the light-emitting element (ES) according to any one of the second to eighteenth aspects, such that the first quantum dot (41, 141) includes a first core (44) and a first shell (46) covering the first core (44), such that the second quantum dot (51, 151) includes a second core (54) and a second shell (56) covering the second core (54), and such that the first shell (46) and the second shell (56) are made of mutually different materials.

In the foregoing configuration, changing the material that is used as the shell material of a quantum dot can obtain a P-type quantum-dot light-emitting layer and an N-type quantum-dot light-emitting layer, thereby offering a light-emitting element that includes the P-type quantum-dot light-emitting layer and the N-type quantum-dot light-emitting layer.

The light-emitting element (ES) according to a twentieth aspect of the disclosure may be configured, in the light-emitting element (ES) according to any one of the second to nineteenth aspects, such that the first quantum dot (41, 141) includes a first core (44), such that the second quantum dot (51, 151) includes a second core (54), and such that the first core (44) and the second core (54) have mutually equal average particle diameters and are made of materials containing mutually identical main ingredients.

The foregoing configuration can offer a light-emitting element that has high external quantum efficiency, and that emits light of the same color or almost the same color from its P-type quantum-dot light-emitting layer and N-type quantum-dot light-emitting layer.

The light-emitting element (ES) according to a twenty-first aspect of the disclosure may be configured, in the light-emitting element (ES) according to the twentieth aspect, such that the first quantum dot (42, 142) further includes a first shell (46) covering the first core (44), such that the second quantum dot (50, 152) further includes a second shell (56) covering the second core (54), and such that the first shell (46) and the second shell (56) have mutually equal average thicknesses.

The foregoing configuration can offer a light-emitting element that has high external quantum efficiency, and that emits light of the same color or almost the same color from its P-type quantum-dot light-emitting layer and N-type quantum-dot light-emitting layer.

The light-emitting element (ES) according to a twenty-second aspect of the disclosure may be configured, in the light-emitting element (ES) according to any one of the second to nineteenth aspects, such that the first quantum dot (42, 142) includes a first core (44), such that the second quantum dot (50, 152) includes a second core (54), and such that the first core (44) and the second core (54) are made of materials containing mutually different main ingredients.

The foregoing configuration can offer a light-emitting element that has high external quantum efficiency, and that emits light of the same color or almost the same color from its P-type quantum-dot light-emitting layer and N-type quantum-dot light-emitting layer. The foregoing configuration can also offer a light-emitting element that has high external quantum efficiency, and that emits light of different colors from its P-type quantum-dot light-emitting layer and N-type quantum-dot light-emitting layer.

The light-emitting element (ES) according to a twenty-third aspect of the disclosure may be configured, in the light-emitting element (ES) according to the twenty-second or twenty-third aspect, such that one of the first core (44) and the second core (54) contains Cd or Pb, and such that the other one of the first core (44) and the second core (54) does not contain Cd or Pb.

The foregoing configuration can keep the coloration of the light-emitting element favorable while reducing the volume of heavy metal within the light-emitting element.

The light-emitting element (ES) according to a twenty-fourth aspect of the disclosure may be configured, in the light-emitting element (ES) according to the twenty-third aspect, such that one of the first core (44) and the second core (54) contains at least one semiconductor material selected from the group consisting of CdSe, CdS, CdTe, PbSe and PbS, and such that the other one of the first core (44) and the second core (54) contains at least one semiconductor material selected from the group consisting of InP, ZnTe, ZnSe, ZnS and ZnTeSe.

The light-emitting element (ES) according to a twenty-fifth aspect of the disclosure may be configured, in the light-emitting element (ES) according to any one of the twenty-second to twenty-third aspects, such that the first core (44) contains at least one semiconductor material selected from the group consisting of CdSe, CdS, ZnTe and ZnSe, and such that the second core (54) contains at least one semiconductor material selected from the group consisting of CdTe, PbSe and InP.

The foregoing configuration voltage can improve the probability that carriers are generated in the boundary surface between the P-type quantum-dot light-emitting layer and N-type quantum-dot light-emitting layer.

The light-emitting element (ES) according to a twenty-sixth aspect of the disclosure may be configured, in the light-emitting element (ES) according to any one of the first to twenty-fifth aspects, such that the emission wavelength band of the P-type quantum-dot light-emitting layer (40, 140) and the emission wavelength band of the N-type quantum-dot light-emitting layer (50, 150) have an overlap, and the P-type quantum-dot light-emitting layer (40, 140) and the N-type quantum-dot light-emitting layer (50, 150) each have an emission peak wavelength in a portion where the emission wavelength bands overlap each other.

The foregoing configuration can offer a light-emitting element that has high external quantum efficiency, and that emits light of the same color or almost the same color from its P-type quantum-dot light-emitting layer and N-type quantum-dot light-emitting layer.

The light-emitting element (ES) according to a twenty-seventh aspect of the disclosure may be configured, in the light-emitting element (ES) according to any one of the first to nineteenth aspects and the twenty-second to twenty-fifth aspects, such that the color of emitted light from the P-type quantum-dot light-emitting layer (40, 140) and the color of emitted light from the N-type quantum-dot light-emitting layer (50, 150) are different, and such that the light-emitting element emits light of a mixed color with the color of emitted light from the P-type quantum-dot light-emitting layer (40,140) and the color of emitted light from the N-type quantum-dot light-emitting layer (50, 150) being mixed together.

The foregoing configuration can offer a light-emitting element that emits light of a mixed color with the color of emitted light from its P-type quantum-dot light-emitting layer and the color of emitted light from its N-type quantum-dot light-emitting layer being mixed together.

The light-emitting element (ES) according to a twenty-eighth aspect of the disclosure may be configured, in the light-emitting element (ES) according to the twenty-seventh aspect, such that the forbidden band (44B) of the first core (44) is wider than the forbidden band (54B) of the second core (54).

In the foregoing configuration, hole mobility is high, thus enabling the turn-on voltage to be lowered.

The light-emitting element (ES) according to a twenty-ninth aspect of the disclosure may be configured, in the light-emitting element (ES) according to the twenty-seventh or twenty-eighth aspect, such that the mixed color is white.

A light-emitting device (2, 80, 90, 100, 110) according to a thirtieth aspect of the disclosure includes the light-emitting element (ES) according to any one of the first to twenty-ninth aspects.

The light-emitting device (2, 80, 90, 100, 110) according to a thirty-first aspect of the disclosure may further include a color filter (70).

The light-emitting device (2, 80, 90, 100, 110) according to a thirty-second aspect of the disclosure may further include a wavelength conversion layer (71, 77).

The light-emitting device (2) according to a thirty-third aspect of the disclosure may be, in the light-emitting device (2) according to any one of the thirtieth to thirty-second aspects, a display device (2).

The light-emitting device (80, 90, 100, 110) according to a thirty-fourth aspect of the disclosure may be, in the light-emitting device (80, 90, 100, 110) according to any one of the thirtieth to thirty-second aspects, a lighting device (80, 90, 100, 110).

The light-emitting device (80) according to a thirty-fifth aspect of the disclosure may be configured, in the light-emitting device (80) according to the thirty-fourth aspect, such that the lighting device is a point light source (80).

The light-emitting device (90) according to a thirty-sixth aspect of the disclosure may be configured, in the light-emitting device (90) according to the thirty-fourth aspect, such that the lighting device is a linear light source (90).

The light-emitting device (100, 110) according to a thirty-seventh aspect of the disclosure may be configured, in the light-emitting device (100, 110) according to the thirty-fourth aspect, such that the lighting device is a planar light source (100, 110).

The present disclosure is not limited to the foregoing embodiments. Various modifications can be devised within the scope of the claims. An embodiment that is obtained in combination, as appropriate, with the technical means disclosed in the respective embodiments is also included in the technical scope of the present disclosure. Furthermore, combining the technical means disclosed in the respective embodiments can form a new technical feature.

1. A light-emitting element comprising:
a negative electrode; a positive electrode; and at least one pair of light-emitting layers formed between the negative electrode and the positive electrode,
wherein the at least one pair of light-emitting layers includes, in a stated order from the cathode, a first quantum-dot light-emitting layer and a second quantum-dot light-emitting layer adjacent to each other, the first quantum-dot light-emitting layer including a first quantum dot, the second quantum-dot light-emitting layer including a second quantum dot, and
a Fermi level of the first quantum dot is closer to a vacuum energy level than a Fermi level of the second quantum dot is.

2. The light-emitting element according to claim 1, wherein
the first quantum-dot light-emitting layer is composed of a P-type quantum-dot light-emitting layer.

3-4. (canceled)

5. The light-emitting element according to claim 1,
wherein the first quantum dot includes a first core,
wherein the second quantum dot includes a second core,
wherein ionization energy of the first core is smaller than ionization energy of the second core, and
wherein an electron affinity of the first core is smaller than an electron affinity of the second core.

6. The light-emitting element according to claim 1,
wherein the Fermi level of the first quantum dot is located closer to a valence band of the first quantum dot than to a center of a forbidden band of the first quantum dot, and
wherein the Fermi level of the second quantum dot is located closer to a conduction band of the second quantum dot than to a center of a forbidden band of the second quantum dot.

7. The light-emitting element according to claim 6, wherein a sum of an energy difference between the Fermi level of the first quantum dot and an upper end of the valence band of the first quantum dot, and an energy difference between the Fermi level of the second quantum dot and a lower end of the conduction band of the second quantum dot is 1.0 eV or smaller.

8. The light-emitting element according to claim 6, wherein a sum of an energy difference between the Fermi level of the first quantum dot and an upper end of the valence band of the first quantum dot, and an energy difference between the Fermi level of the second quantum dot and a lower end of the conduction band of the second quantum dot is 0.5 eV or smaller.

9. The light-emitting element according to claim 1, wherein
the first quantum dot includes a first nanocrystal and a first ligand coordinating with the first nanocrystal,
the second quantum dot includes a second nanocrystal and a second ligand coordinating with the second nanocrystal, and
the first ligand and the second ligand are formed of mutually different materials.

10. The light-emitting element according to claim 9, wherein
the first ligand exhibits an electron-withdrawing capability, and
the second ligand exhibits an electron-donating capability.

11. (canceled)

12. The light-emitting element according to claim 9, wherein
the first ligand includes at least one compound selected from the group consisting of compounds expressed by the following structural formula (1), where X1 is a functional group coordinating with the first nanocrystal and denotes a thiol group, a carboxyl group or an amino group, or X1 denotes a thiolate anion, a carboxylate anion or an aminolate anion, where R1 includes at least one selected from a triazole skeleton, a triazine skeleton, a thiophene skeleton, a furan skeleton, a thiazole skeleton, an oxazole skeleton, an oxadiazole skeleton and a thiothiazole skeleton, and
the second ligand includes at least one compound selected from the group consisting of compounds expressed by the following structural formula (7), where X2 is a functional group coordinating with the second nanocrystal and denotes a thiol group, a carboxyl group or an amino group, or X2 denotes an ammonium ion, or X2 denotes a thiolate anion, a carboxylate anion or an aminolate anion, where R4 includes any one or more selected from a carbazole skeleton, an acridine skeleton, a phenoxazine skeleton and a phenazine skeleton and has a nitrogen-containing aromatic ring, where R4 is a nitrogen atom forming a nitrogen-containing aromatic ring and joins with a benzene ring expressed by the following structural formula (7):

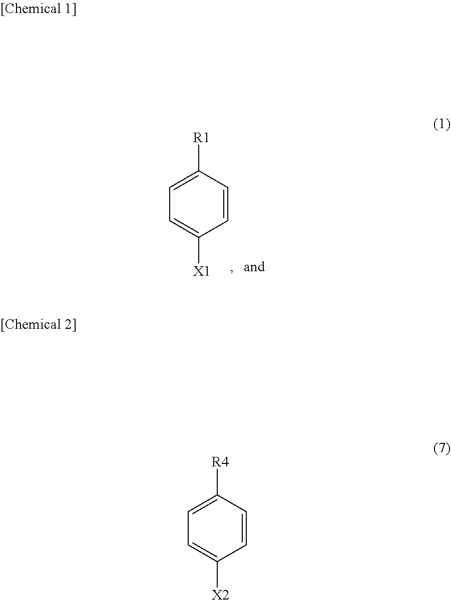

13. The light-emitting element according to claim 12, wherein
the at least one compound expressed by the structural formula (1) is at least one compound selected from the group consisting of compounds expressed by the following structural formulas (2) to (6), where X1 may be identical or different between the structural formulas, where R2 and R3 may be identical to or different from each other, where R2 and R3 each independently denote a hydrogen atom, a substituted or non-substituted alkyl group having 1 to 12 carbon atoms, or a substituted or non-substituted phenyl group or biphenyl group, and
the at least one compound expressed by the structural formula (7) is at least one compound selected from the group consisting of compounds expressed by the following structural formulas (8) to (11), where X2 may be identical or different between the structural formulas, where R5 and R6 may be identical to or different from each other, where R5 and R6 each independently denote a hydrogen atom, a substituted or non-substituted alkyl group having 1 to 12 carbon atoms, or a substituted or non-substituted phenyl group or biphenyl group:

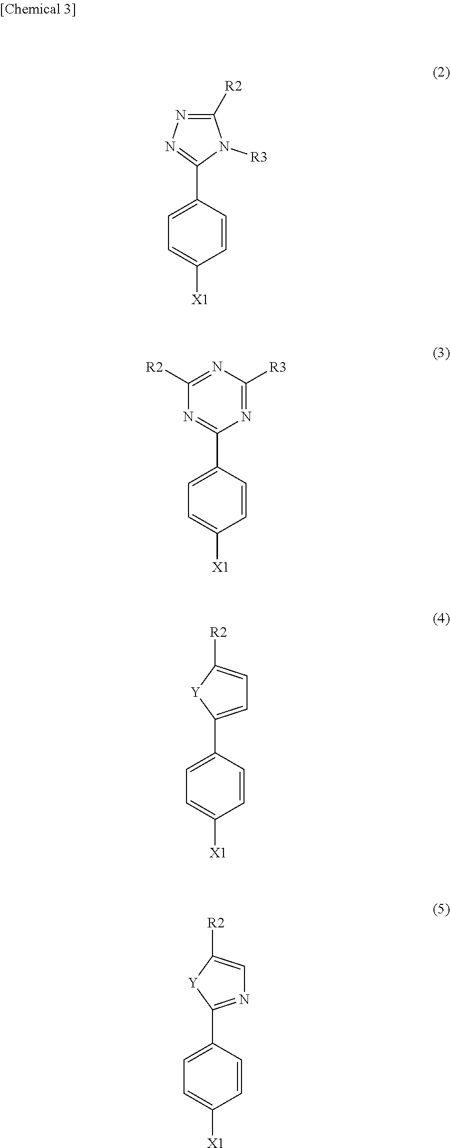

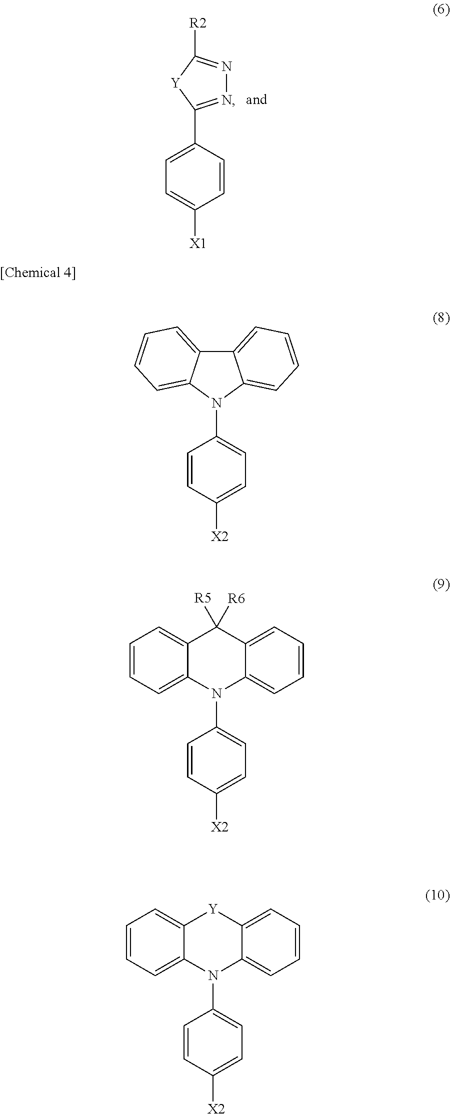

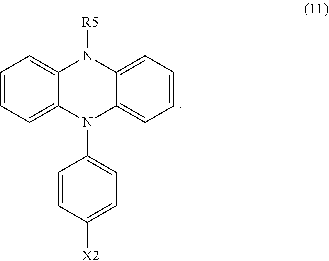

14. The light-emitting element according to claim 9, wherein the first ligand and the second ligand are 1 nm or greater long.

15-17. (canceled)

18. The light-emitting element according to claim 1, wherein
the first quantum dot includes a first core containing an acceptor as a dope ingredient, and
the second quantum dot includes a second core containing a donor as a dope ingredient.

19. The light-emitting element according to claim 1, wherein
the first quantum dot includes a first core and a first shell covering the first core,
the second quantum dot includes a second core and a second shell covering the second core, and
the first shell and the second shell are made of mutually different materials.

20. The light-emitting element according to claim 1, wherein
the first quantum dot includes a first core,
the second quantum dot includes a second core, and
the first core and the second core have mutually equal average particle diameters and are made of materials containing mutually identical main ingredients.

21. (canceled)

22. The light-emitting element according to claim 1, wherein
the first quantum dot includes a first core,
the second quantum dot includes a second core, and
the first core and the second core are made of materials containing mutually different main ingredients.

23-25. (canceled)

26. The light-emitting element according to claim 1, wherein an emission wavelength band of the first quantum-dot light-emitting layer and an emission wavelength band of the second quantum-dot light-emitting layer have an overlap, and the first quantum-dot light-emitting layer and the second quantum-dot light-emitting layer each have an emission peak wavelength in a portion where the emission wavelength bands overlap each other.

27. The light-emitting element according to claim 1, wherein
a color of emitted light from the first quantum-dot light-emitting layer and a color of emitted light from the second quantum-dot light-emitting layer are different, and
the light-emitting element emits light of a mixed color with the color of emitted light from the first quantum-dot light-emitting layer and the color of emitted light from the second quantum-dot light-emitting layer being mixed together.

28-37. (canceled)

38. The light-emitting element according to claim 2, wherein the second quantum-dot light-emitting layer is composed of an N-type quantum-dot light-emitting layer.

39. The light-emitting element according to claim 38, wherein
the first quantum-dot light-emitting layer includes a P-type quantum dot and exhibits a higher hole transportability than an electron transportability, and
the second quantum-dot light-emitting layer includes an N-type quantum dot and exhibits a higher electron transportability than a hole transportability.

40. The light-emitting element according to claim 38,
wherein the first quantum-dot light-emitting layer includes a P-type quantum dot, and hole mobility of the P-type quantum dot is higher than electron mobility of the P-type quantum dot, and
wherein the second quantum-dot light-emitting layer includes an N-type quantum dot, and electron mobility of the N-type quantum dot is higher than hole mobility of the N-type quantum dot.

41. The light-emitting element according to claim 26, wherein
the emission wavelength band of the first quantum-dot light-emitting layer and the emission wavelength band of the second quantum-dot light-emitting layer have an overlap, and the first quantum-dot light-emitting layer and the second quantum-dot light-emitting layer emit light of an identical color or a substantially identical color.

42. The light-emitting element according to claim 1, comprising a different layer formed between the first quantum-dot light-emitting layer and the second quantum-dot light-emitting layer.

43. The light-emitting element according to claim 42, wherein the different layer is a thin layer that allows an electron to tunnel.
